(19) United States
(12) Patent Application Publication
(10) Pub. No.: US 2024/0334619 A1
(43) Pub. Date: Oct. 3, 2024

(54) ELECTRONIC DEVICE

(71) Applicant: Mitsubishi Electric Corporation, Tokyo (JP)

(72) Inventors: Eri Kuwahara, Tokyo (JP); Takashi Ohara, Tokyo (JP); Kazuhisa Tamura, Tokyo (JP)

(73) Assignee: Mitsubishi Electric Corporation, Tokyo (JP)

(21) Appl. No.: 18/363,440

(22) Filed: Aug. 1, 2023

(30) Foreign Application Priority Data
Mar. 27, 2023 (JP) 2023-049664

(51) Int. Cl. H05K 5/00; H05K 7/20

(52) U.S. Cl. CPC H05K 5/0013; H05K 7/20409; H05K 7/2049

(57) ABSTRACT

In order to provide an electronic device capable of securing a sufficient heat dissipation path while reducing assembly man-hours, the electronic device includes: a substrate on which an electronic component is packaged; a case in which a substrate insertion opening portion is provided, a slide groove through which a substrate is inserted by sliding is formed on both sidewalls, and the substrate is contained by being inserted in the slide groove from the substrate insertion opening portion; and a cover which is coupled to the case to block the substrate insertion opening portion of the case, the case being provided with a case side positioning portion for positioning the substrate; and the cover being provided with a cover side positioning portion for positioning the substrate.

### BACKGROUND OF THE INVENTION

### 1. Field of the Invention

The present application relates to an electronic device.

### 2. Description of the Related Art

A general configuration of a known electronic device is a configuration in which an electronic substrate is incorporated in a housing composed of a case and a cover; and in the case of arranging the electronic substrate in the housing, screws are often used for fixing between the electronic substrate and the housing.

Furthermore, there is often used a structure in which an electronic component and the housing are brought into contact by using material with good heat conductivity between them so that heat generated from the electronic component packaged on the electronic substrate is released to a surface portion of the housing or the like of the electronic device, the surface portion being exposed to the air.

For example, Patent Document 1 is a configuration in which after an electronic substrate fixed in advance to a metal member with good heat conductivity by screws is inserted in a housing, the electronic substrate and the housing are further fixed by screws and the electronic substrate and the housing are brought into contact by using the metal member between them to secure a heat dissipation path.

Patent Document 1: JP, 4770933,B

The above-mentioned known electronic device disclosed in Patent Document 1 is a configuration which is fixed by using screws between a first substrate and a frame, between a second substrate and the frame, between the frame and a case, and between a heat dissipation block and the case; accordingly, a problem exists in that assembly man-hours is increased.

Furthermore, a problem exists in that it is not a configuration that can use a member, which reduces heat resistance of a path through which heat generated by an electronic component such as TIM (Thermal Interface Material) between an electrical circuit unit and the case is conducted to the housing.

### SUMMARY OF THE INVENTION

The present application is to disclose a technique for solving the foregoing problem and has an object to provide an electronic device capable of securing a sufficient heat dissipation path while reducing assembly man-hours.

An electronic device disclosed in the present application is an electronic device which includes: a substrate on which an electronic component is packaged; a case in which a substrate insertion opening portion is provided, a slide groove through which the substrate is inserted by sliding is formed on both sidewalls, and the substrate is contained by being inserted in the slide groove from the substrate insertion opening portion; and a cover which is coupled to the case to block the substrate insertion opening portion of the case. In the electronic device, the case is provided with a case side positioning portion which has a part of positioning a thickness direction of the substrate and a part of positioning a direction perpendicular to the thickness of the substrate; and the cover is provided with a cover side positioning portion which has a part of positioning the thickness direction of the substrate and a part of positioning the direction perpendicular to the thickness of the substrate.

Furthermore, an electronic device disclosed in the present application is an electronic device which includes: a first substrate on which an electronic component is packaged; a second substrate on which an electronic component is packaged; a case in which a substrate insertion opening portion and an attaching opening portion are provided, a first slide groove through which the first substrate is inserted by sliding and a second slide groove through which the second substrate is inserted by sliding are formed on both sidewalls, the first substrate is contained by being inserted in the first slide groove from the substrate insertion opening portion, and the second substrate is contained by being inserted in the second slide groove from the substrate insertion opening portion; and a cover which is coupled to the case to block the substrate insertion opening portion of the case. In the electronic device, the case is provided with a case side first positioning portion which has a part of positioning a thickness direction of the first substrate and a part of positioning a direction perpendicular to a thickness of the first substrate and a case side second positioning portion which has a part of positioning a thickness direction of the second substrate and a part of positioning a direction perpendicular to a thickness of the second substrate; the cover is provided with a cover side first positioning portion which has a part of positioning the thickness direction of the first substrate and a part of positioning the direction perpendicular to the thickness of the first substrate and a cover side second positioning portion which has a part of positioning the thickness direction of the second substrate and a part of positioning the direction perpendicular to the thickness of the second substrate; and a relay member connecting the first substrate and the second substrate is provided between the first substrate and the second substrate.

According to the electronic device disclosed in the present application, there can be obtained an electronic device capable of securing a sufficient heat dissipation path while reducing assembly man-hours.

The foregoing and other object, features, aspects, and advantages of the present application will become more apparent from the following detailed description of the present application when taken in conjunction with the accompanying drawings.

### BRIEF DESCRIPTION OF THE DRAWINGS

FIG. 1 is a perspective view showing an electronic device according to Embodiment 1;

FIG. 2 is a perspective view showing a dismantled state of the electronic device according to Embodiment 1;

FIG. 3 is a perspective view showing a dismantled state of the electronic device according to Embodiment 1;

FIG. 4 is a plan view showing the electronic device according to Embodiment 1;

FIG. 5 is a sectional view taken along the line A-A of FIG. 4 showing the electronic device according to Embodiment 1;

FIG. 6 is an enlarged sectional view taken along the line B-B of FIG. 4 showing the electronic device according to Embodiment 1;

FIG. 7 is an enlarged sectional view taken along the line C-C of FIG. 4 showing the electronic device according to Embodiment 1;

FIG. 8 is a plan view showing the arrangement of an electronic component in the electronic device according to Embodiment 1;

FIG. 9 is a perspective view of an electronic device according to Embodiment 2;

FIG. 10 is a perspective view showing a dismantled state of the electronic device according to Embodiment 2;

FIG. 11 is a perspective view showing a dismantled state of the electronic device according to Embodiment 2;

FIG. 12 is a plan view showing the electronic device according to Embodiment 2;

FIG. 13 is a sectional view taken along the line A1-A1 of FIG. 12 showing the electronic device according to Embodiment 2;

FIG. 14 is an enlarged sectional view taken along the line

B1-B1 of FIG. 12 showing the electronic device according to Embodiment 2;

FIG. 15 is an enlarged sectional view taken along the line A1-A1 of FIG. 12 showing the electronic device according to Embodiment 2;

FIG. 16 is a plan view showing the arrangement of an electronic component in the electronic device according to Embodiment 2;

FIG. 17 is a perspective view showing an electronic device according to Embodiment 3;

FIG. 18 is a perspective view showing a dismantled state of the electronic device according to Embodiment 3;

FIG. 19 is a perspective view showing a dismantled state of the electronic device according to Embodiment 3;

FIG. 20 is a plan view showing the electronic device according to Embodiment 3;

FIG. 21 is a sectional view taken along the line A2-A2 of

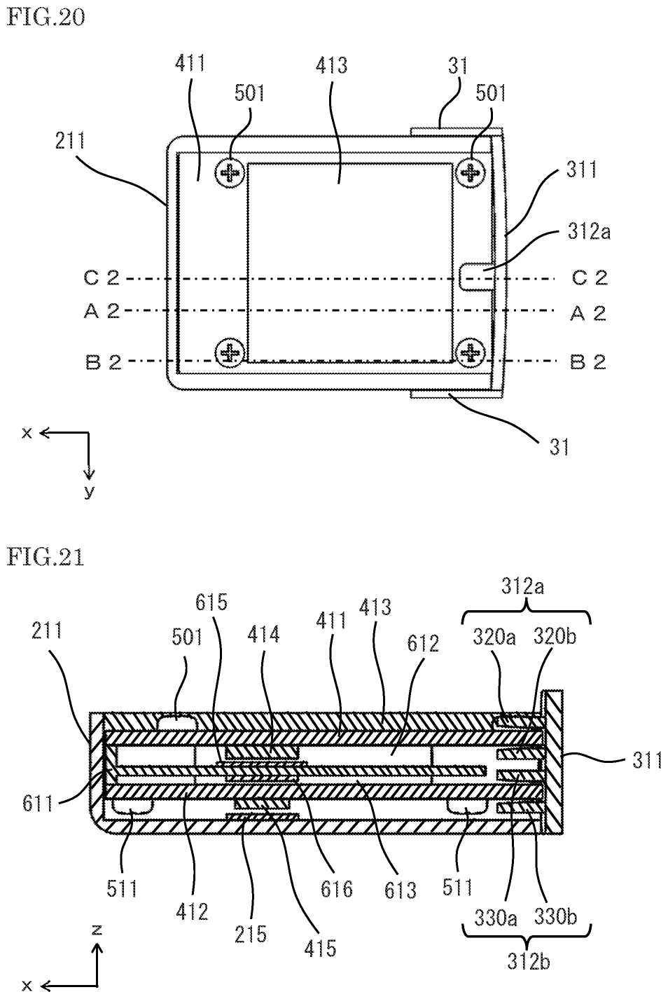

FIG. 20 showing the electronic device according to Embodiment 3;

FIG. 22 is an enlarged sectional view taken along the line B2-B2 of FIG. 20 showing the electronic device according to Embodiment 3;

FIG. 23 is an enlarged sectional view taken along the line C2-C2 of FIG. 20 showing the electronic device according to Embodiment 3;

FIG. 24 is a plan view showing the arrangement of an electronic component in the electronic device according to Embodiment 3; and

FIG. 25 is a plan view showing the arrangement of an electronic component in the electronic device according to Embodiment 3.

### DETAILED DESCRIPTION OF THE INVENTION

### Embodiment 1

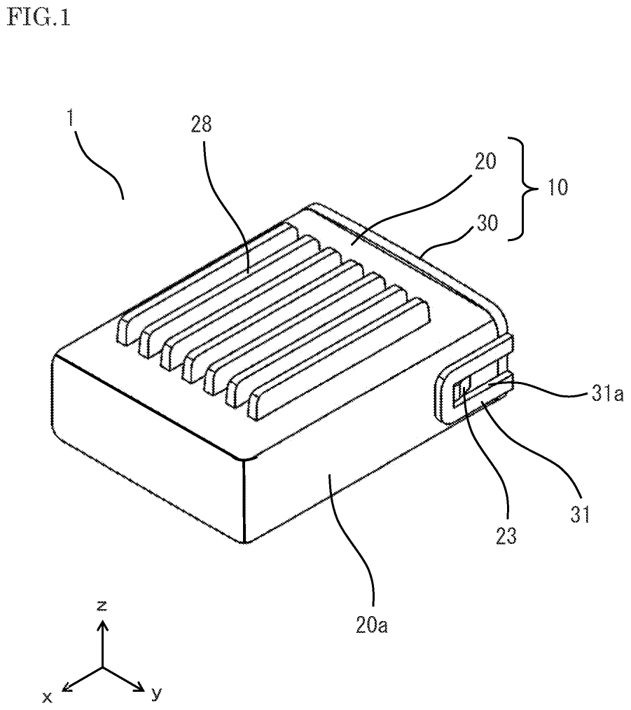

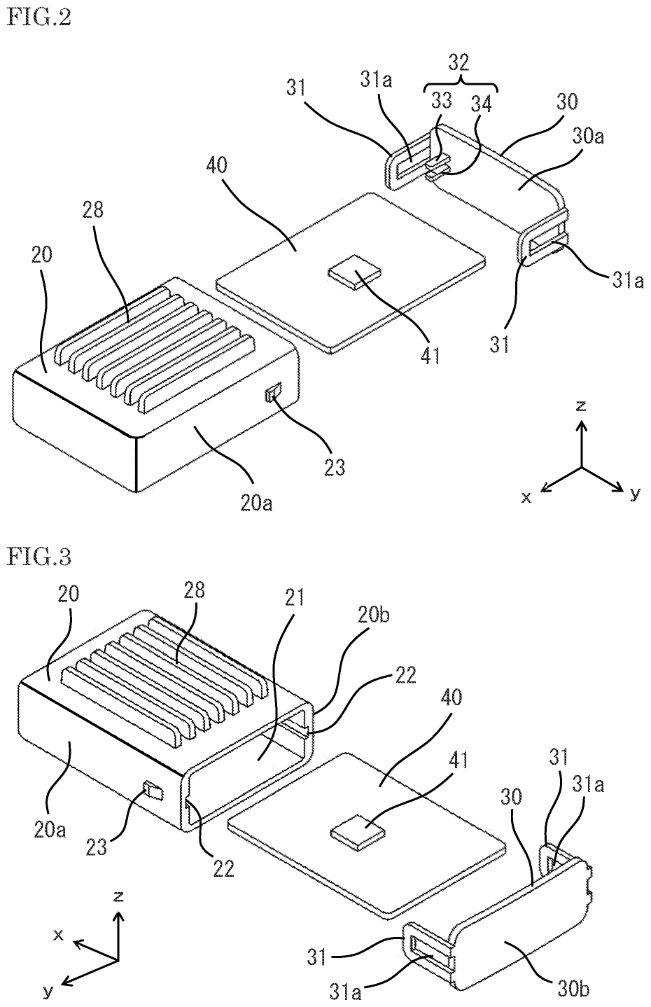

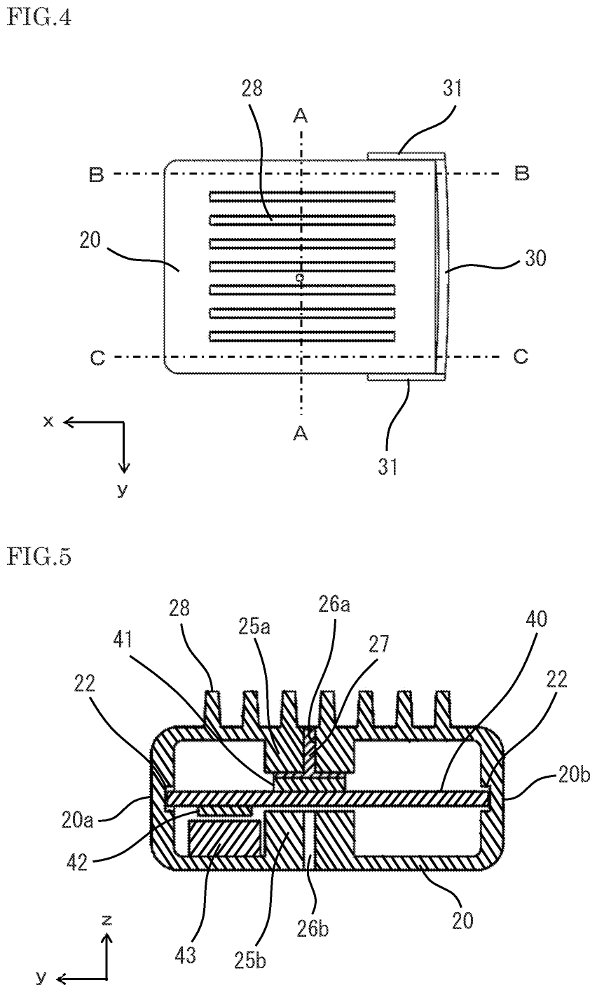

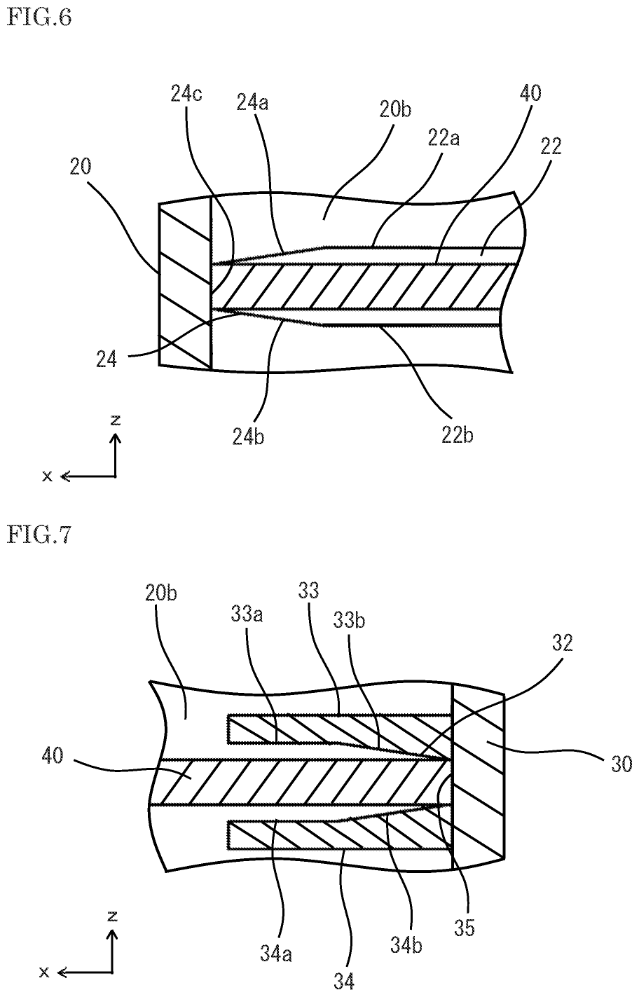

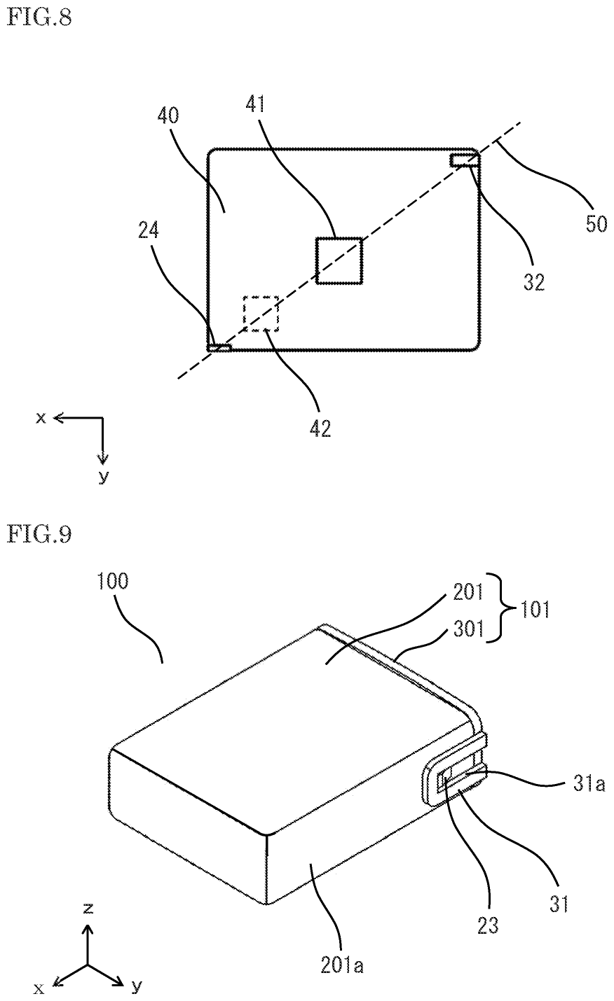

Hereinafter, Embodiment 1 of the present application will be described on the basis of FIG. 1 to FIG. 8. Then, in each of the drawings, identical or equivalent members and parts will be described with the same reference numerals (and letters) assigned thereto. FIG. 1 is a perspective view showing an electronic device according to Embodiment 1. FIG. 2 is a perspective view showing a dismantled state of the electronic device according to Embodiment 1 and is the perspective view seen from a positive direction of an x axis. FIG. 3 is a perspective view showing a dismantled state of the electronic device according to Embodiment 1 and is the perspective view seen from a negative direction of the x axis. FIG. 4 is a plan view in an xy flat surface showing the electronic device according to Embodiment 1. FIG. 5 is a sectional view in a yz flat surface taken along the line A-A of FIG. 4 showing the electronic device according to Embodiment 1. FIG. 6 is an enlarged sectional view in an xz flat surface taken along the line B-B of FIG. 4 showing the electronic device according to Embodiment 1. FIG. 7 is an enlarged sectional view in the xz flat surface taken along the line C-C of FIG. 4 showing the electronic device according to Embodiment 1. FIG. 8 is a plan view showing the arrangement of an electronic component in the electronic device according to Embodiment 1 and is a schematic view of the xy flat surface.

FIG. 1 is the perspective view of an electronic device 1 and shows a housing 10 in which a substrate 40 having an expanse in the xy flat surface is contained inside. The housing 10 is mainly composed of a case 20 in which the substrate 40 is inserted by sliding and a cover 30 which is overlapped with the case 20 in an x axis direction and blocks a substrate insertion opening portion 21 (to be described later) of the case 20. An engagement convex portion 23 is provided on a sidewall of the case 20 and the cover 30 is provided with a close-fitting piece 31 having an engagement concave portion 31a that is engaged with the engagement convex portion 23 of the case 20. Furthermore, a fin 28 which enhances a heat dissipation effect is provided on an upper surface of the case 20.

The electronic device 1 is connected to an external power supply device (not shown in the drawing) and a communication device (not shown in the drawing) via a connector (not shown in the drawing) . There is a case where the electronic device 1 is provided with a fastening portion (not shown in the drawing) which is for fastening to other portion on the case 20 when one surface of the case 20 is attached to a stay or the like as a mounting surface.

FIG. 2 and FIG. 3 are the exploded perspective view of the electronic device 1 and show that the substrate 40 which is to be contained in an internal space between the case 20 and the cover 30 is provided in a prescribed location.

The case 20 is a substantially cuboid shape and is a hollow shape so that the substrate 40 on which an electronic component 41 is packaged can be contained inside. As shown in FIG. 3, the case 20 has the substrate insertion opening portion 21 on one surface of the yz flat surface; and a slide groove 22 through which the substrate 40 is matched when the substrate 40 is inserted by sliding in the x axis direction from the substrate insertion opening portion 21 of the case 20 is provided along the x axis direction. The size in a z axis direction of the slide groove 22 is larger than the thickness of the substrate 40.

Two surfaces of sidewalls 20a, 20b of an xz flat surface of the case 20 near the substrate insertion opening portion 21 are each provided with the engagement convex portion 23. The engagement convex portion 23 fastens the case 20 and the cover 30 by fitting with the engagement concave portion 31a of the close-fitting piece 31 provided on the cover 30. A wedge shape, or a tapered shape such as a trapezoid, or a curved shape is included as an example of the shape of the engagement convex portion 23.

The case 20 is formed of material with high heat conductivity, for example, metal, heat conductive resin, or material in which metal plating is applied to heat conductive resin. Further, it is desirable to apply surface finishing, for example, alumite treatment or coating, which enhances a radiation rate, to the outside surface of the case 20.

The cover 30 is a substantially U shape that is such as to block the substrate insertion opening portion 21 of the case 20. Two surfaces of an xz flat surface of the cover 30 are each provided with the close-fitting piece 31 having the engagement concave portion 31a. It may be permissible if the shape of the engagement concave portion 31a of the close-fitting piece 31 is fitted with the engagement convex portion 23 provided on the sidewalls 20a, 20b of the case 20. The cover side positioning portion 32 is provided at one place in a yz flat surface of the cover 30. The cover side positioning portion 32 is provided at the position of the cover 30 on a diagonal with respect to the case side positioning portion 24 (to be described later).

An inner surface 30a and an outer surface 30b of the yz flat surface of the cover 30 are a shape which is parallel to the yz flat surface or expanded in a crescent shape in a positive direction of the x axis in a state being not attached to the case 20. The cover 30 is formed of metal plate material, resin, rubber, or the like.

The substrate 40 is one in which a plurality of electronic components is packaged on a substantially rectangular base material. The size of an xy flat surface of the substrate 40 is substantially equivalent to an xy flat surface of the housing 10; and the electronic component 41 is packaged on an upper surface of the substrate 40 and an electronic component 42 is packaged on a lower surface of the substrate 40. Glass epoxy material, thermosetting resin, fluorine resin, metal material and the like are used by being combined on the base material.

An internal structure of the electronic device 1 will be described on the basis of FIG. 4 through FIG. 7. A case side positioning portion 24 is provided at one place on the case 20 at a position most away from the cover 30 on the slide groove 22 on the line B-B of FIG. 4 and is provided at a position on the diagonal of the cover side positioning portion 32.

The shape of the case side positioning portion 24 will be described using FIG. 6. The case side positioning portion 24 is composed of an inclined portion 24a, an inclined portion 24b, and a wall surface 24c of a yz flat surface. The inclined portion 24a and the inclined portion 24b are inclined so that the width of the slide groove 22 becomes narrower than the width of the other slide groove 22 as an upper surface 22a and a lower surface 22b of an xy flat surface of the slide groove 22 are away from the cover 30, respectively, and the wall surface 24c comes in contact with the inclined portion 24a and the inclined portion 24b. The size of a gap in a z axis direction, the gap being formed by the inclined portion 24a and the inclined portion 24b, is equivalent to or smaller than the thickness of the substrate 40.

A part of positioning a z axis direction in a thickness direction of the substrate 40 of the case side positioning portion 24 is the inclined portion 24a and the inclined portion 24b of the slide groove 22; and a part of positioning an x axis direction in a direction perpendicular to the thickness of the substrate 40 of the case side positioning portion 24 is the wall surface 24c of the yz flat surface which comes in contact with the inclined portion 24a and the inclined portion 24b of the case 20.

The substrate 40 is inserted in the slide groove 22 and a top end portion of the substrate 40 is inserted between the inclined portion 24a and the inclined portion 24b of the slide groove 22, whereby the z axis direction in the thickness direction of the substrate 40 is positioned. Then, a top end surface of the substrate 40 is brought into contact with the wall surface 24c, whereby the x axis direction in the direction perpendicular to the thickness of the substrate 40 is positioned.

The cover side positioning portion 32 of the cover 30 is provided at one place on the line C-C of FIG. 4. The shape of the cover side positioning portion 32 will be described using FIG. 7. The cover side positioning portion 32 is composed of a first sandwiching piece 33 and a second sandwiching piece 34 which are protruded in the x axis direction on the case 20 side from the inner surface 30a on the case 20 side in the yz flat surface of the cover 30.

The first sandwiching piece 33 and the second sandwiching piece 34 have a plane portion 33a and a plane portion 34a, respectively, which are sandwiched by the first sandwiching piece 33 and the second sandwiching piece 34. The plane portion 33a of the first sandwiching piece 33 has an inclined portion 33b inclined to the substrate 40 side as it goes toward the inner surface 30a of the cover 30; and the plane portion 34a of the second sandwiching piece 34 has an inclined portion 34b inclined to the substrate 40 side as it goes toward the inner surface 30a of the cover 30.

The size of a gap in the z axis direction which is formed by the inclined portion 33b of the first sandwiching piece 33 and the inclined portion 34b of the second sandwiching piece 34 is equivalent to or smaller than the thickness of the substrate 40. The gap formed by the inclined portion 33b and the inclined portion 34b becomes small as it goes toward the inner surface 30a of the cover 30.

A part of positioning the z axis direction in the thickness direction of the substrate 40 of the cover side positioning portion 32 is the inclined portion 33b of the first sandwiching piece 33 and the inclined portion 34b of the second sandwiching piece 34 which are provided in a protruding condition on the inner surface 30a of the cover 30; and a part of positioning the x axis direction in the direction perpendicular to the thickness of the substrate 40 of the cover side positioning portion 32 is a wall surface 35 of the inner surface 30a of the cover 30 which comes in contact with the inclined portion 33b of the first sandwiching piece 33 and the inclined portion 34b of the second sandwiching piece 34.

After the substrate 40 is inserted in the case 20, the engagement concave portion 31a of the close-fitting piece 31 provided on the cover 30 is engaged with the engagement convex portion 23 of the case 20 to block the substrate insertion opening portion 21 of the case 20, whereby the cover 30 is attached to the case 20. With this manner, the inclined portion 33b of the first sandwiching piece 33 and the inclined portion 34b of the second sandwiching piece 34 of the cover side positioning portion 32, which are provided in a protruding condition on the inner surface 30a of the cover 30, are inserted in a rear end portion of the substrate 40; thus, the z axis direction in the thickness direction of the substrate 40 is positioned. Then, the wall surface 35 of the inner surface 30a of the cover 30 is brought into contact with a rear end surface of the substrate 40 and thus the x axis direction in the direction perpendicular to the thickness of the substrate 40 is positioned.

The electronic component 41 with a large amount of heat generation of the electronic components packaged on the substrate 40 is arranged at a position on a substantially straight line 50 of the diagonal connecting the case side positioning portion 24 provided on the case 20 and the cover side positioning portion 32 provided on the cover 30, as shown in FIG. 8.

A peripheral configuration of the substrate 40 on which the electronic component 41 with a large amount of heat generation is packaged will be described using FIG. 5. The case 20 is provided with a convex portion 25a provided in a protruding condition so as to come close to the electronic component 41 at the position of the electronic component 41 with a large amount of heat generation. Furthermore, a convex portion 25b provided in a protruding condition so as to come close to the substrate 40 is provided at the position of the electronic component 41 on a back surface of the substrate 40 on which the electronic component 41 is packaged.

The shape of the convex portion 25a and the convex portion 25b provided on the case 20 has a resemblance in shape to the electronic component 41 in the xy flat surface and is larger than the electronic component 41 so as to be able to entirely cover the electronic component 41. The convex portion 25a is provided with a through hole 26a passing through the inside and the outside of the case 20 at roughly the center of the convex portion. The convex portion 25b is also similarly provided with a through hole 26b passing through the inside and the outside of the case 20.

A gap is provided between the convex portion 25a of the case 20 and the electronic component 41 and between the convex portion 25b of the case 20 and the substrate 40. A heat dissipation material 27 is filled in the through hole 26a and the gap between the convex portion 25a and the electronic component 41. The heat dissipation material may not be filled in the through hole 26b and the gap between the convex portion 25b and the substrate 40.

A fin 28 is provided on the outside of the case 20 at an area at which the convex portion 25a of the case 20 is provided. Heat generated by the electronic component 41 with a large amount of heat generation is conducted to the case 20 via the filled heat dissipation material 27, the convex portion 25a, and the convex portion 25b and is dissipated to the air from the surface of the case 20 and the fin 28.

Furthermore, the electronic component 42 is packaged on the back surface of the substrate 40; and the case 20 is provided with a convex portion 43 provided in a protruding condition so as to come close to the electronic component 42 at the position of the electronic component 42. Heat generated by the electronic component 42 is conducted to the case 20 via the convex portion 43 and is dissipated to the air from the surface of the case 20 and the fin 28.

An assembly method of the electronic device 1 will be described. The thickness direction of the substrate 40 is oriented to the slide groove 22 provided on the case 20; and the substrate 40 is slid in the x axis direction along the slide groove 22 and is inserted in the inside of the case. After the substrate 40 is contained in the case 20, the engagement concave portion 31a of the close-fitting piece 31 provided on the cover 30 is attached so as to be fitted with the engagement convex portion 23 of the case 20.

When the cover 30 is attached to the case 20, the substrate 40 is pressed in the x axis direction by the cover 30 until the top end surface of the substrate 40 comes in contact with the wall surface 24c of the case side positioning portion 24 of the case 20; and the inner surface 30a and the outer surface 30b of the cover become a shape which is expanded in the crescent shape in the negative direction of the x axis or parallel to the yz flat surface. With this manner, the position of the x axis direction of the substrate 40 is determined.

The substrate 40 is sandwiched by the gap surrounded by the inclined portion 24a and the inclined portion 24b of the case side positioning portion 24 of the case 20 and the gap between the first sandwiching piece 33 and the second sandwiching piece 34 of the cover side positioning portion 32 of the cover 30; thus, the position in the axis direction serving as the thickness direction of the substrate 40 is determined. The substrate 40 is contained in the case 20 and the case 20 and the cover 30 are fixed; and then, the heat dissipation material 27 is injected from the through hole 26a provided in the case 20. The heat dissipation material 27 passes through the through hole 26a from the outside of the case 20 and is filled in the gap between the convex portion 25a and the electronic component 41. The heat dissipation material 27 may be made of adhesive and a type which hardens in a semi-solid state after being filled is desirable.

In this manner, in Embodiment 1, the substrate 40 can be arranged on the case 20 in the housing 10 without using other fixing member such as a screw and assembly man-hours can be reduced.

Furthermore, the electronic component 41 with a large amount of heat generation is arranged on the substantially straight line 50 of the diagonal connecting the case side positioning portion 24 of the case 20 and the cover side positioning portion 32 of the cover 30, whereby the electronic component 41 with a large amount of heat generation can be arranged at a position good for positional accuracy within the substrate 40.

If positional accuracy of the electronic component 41 with a large amount of heat generation can be improved, it becomes possible to suppress variation of a gap between the electronic component 41 with a large amount of heat generation and the case 20 and a gap between the substrate 40 on which the electronic component 41 with a large amount of heat generation is packaged and the case 20 and these can be come close.

With this manner, the gap between the convex portion 25a provided on the case 20 and the electronic component 41 and the gap between the convex portion 25b provided on the case 20 and the substrate 40 can be reduced and it becomes possible to secure a sufficient heat dissipation path by a small amount of the heat dissipation material 27.

### Embodiment 2

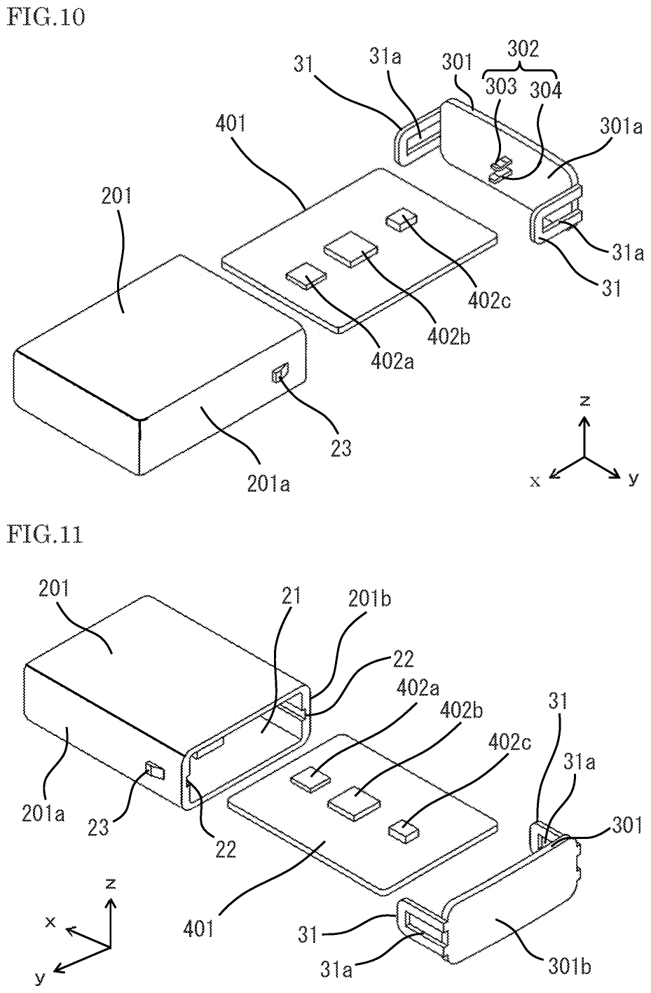

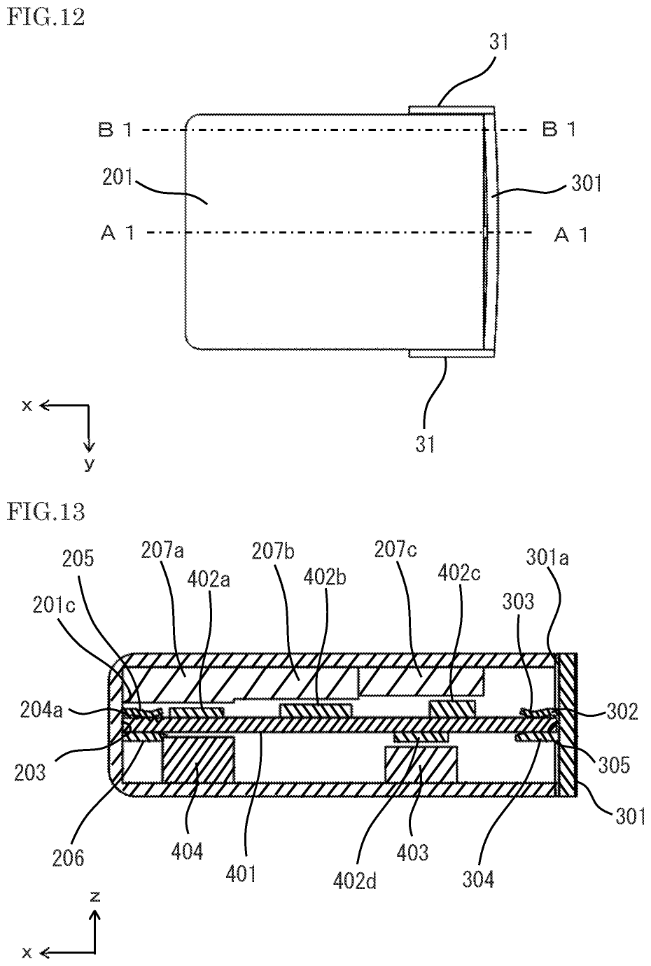

Hereinafter, Embodiment 2 of the present application will be described on the basis of FIG. 9 to FIG. 16. Then, in each of the drawings, identical or equivalent members and parts will be described with the same reference numerals (and letters) assigned thereto. FIG. 9 is a perspective view of an electronic device according to Embodiment 2. FIG. 10 is a perspective view showing a dismantled state of the electronic device according to Embodiment 2 and is the perspective view seen from a positive direction of an x axis. FIG. 11 is a perspective view showing a dismantled state of the electronic device according to Embodiment 2 and the perspective view seen from a negative direction of the x axis. FIG. 12 is a plan view in an xy flat surface showing the electronic device according to Embodiment 2.

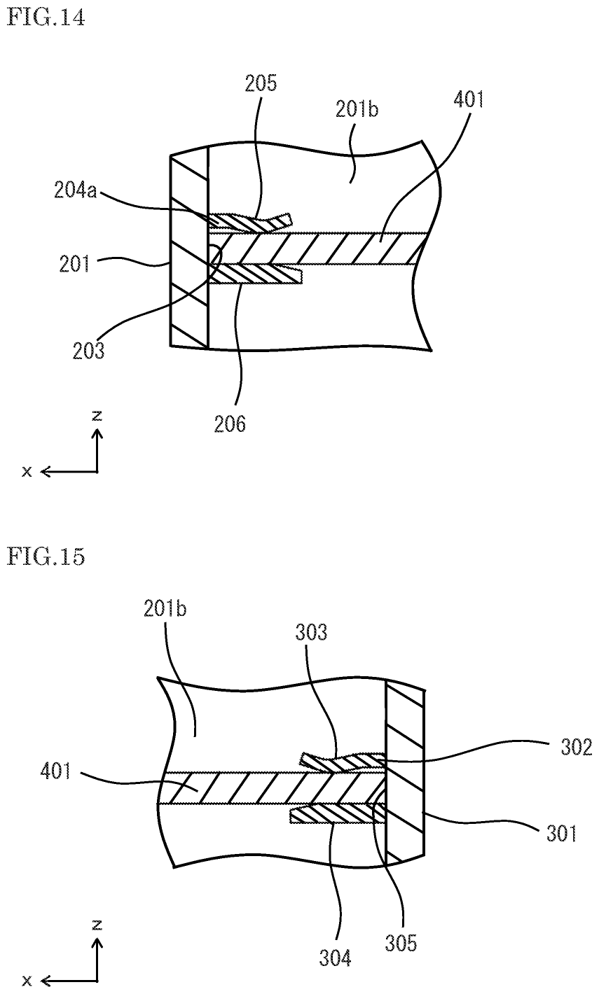

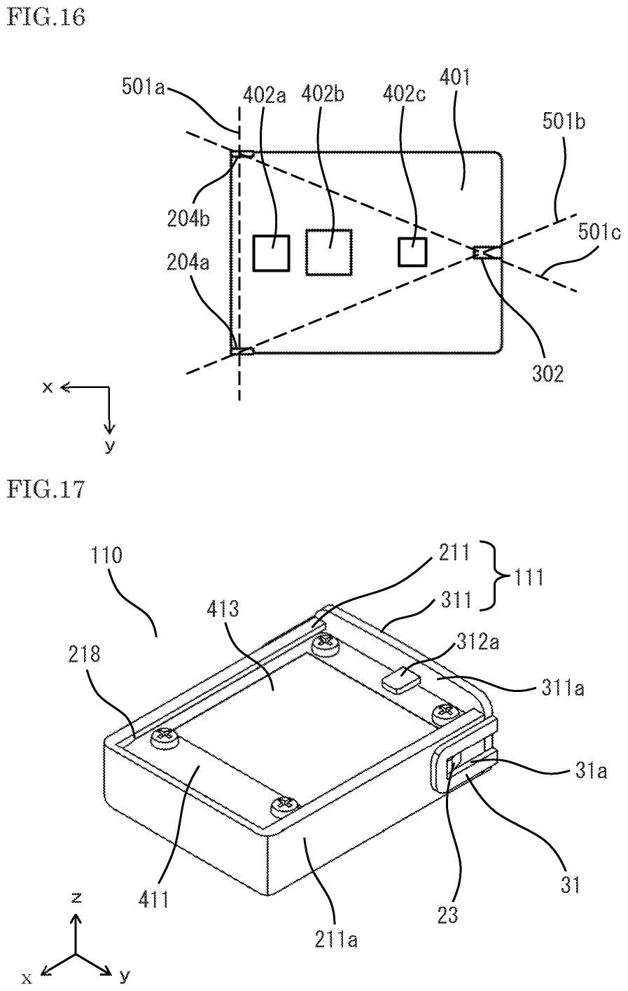

FIG. 13 is a sectional view in an xz flat surface taken along the line A1-A1 of FIG. 12 showing the electronic device according to Embodiment 2. FIG. 14 is an enlarged sectional view in the xz flat surface taken along the line B1-B1 of FIG. 12 showing the electronic device according to Embodiment 2. FIG. 15 is an enlarged sectional view in the xz flat surface taken along the line A1-A1 of FIG. 12 showing the electronic device according to Embodiment 2. FIG. 16 is a plan view showing the arrangement of an electronic component in the electronic device according to Embodiment 2 and is a schematic view of the xy flat surface showing the arrangement of a heating component. The line A1-A1 is a position passing a substantially center of the xy flat surface of a housing 101.

A positioning shape of a case 20 and a cover 30 and a heat withdrawal convex portion of the case 20 of Embodiment 2 of the present application are different from those of the above-mentioned Embodiment 1. In Embodiment 2, the same reference numerals are given to portions common to Embodiment 1 and their description will be omitted; and different points from

Embodiment 1 will be mainly described.

FIG. 9 is a perspective view of an electronic device 100 according to Embodiment 2 and shows a housing 101 in which the substrate 401 having an expanse in the xy flat surface is contained inside. The housing 101 is mainly composed of a case 201 in which the substrate 401 is inserted by sliding and a cover 301 which is overlapped with the case 201 in an x axis direction and blocks a substrate insertion opening portion 21 of the case 201. An engagement convex portion 23 is provided on a sidewall of the case 201 and the cover 301 is provided with a close-fitting piece 31 having an engagement concave portion 31a that is engaged with the engagement convex portion 23 of the case 201.

FIG. 10 and FIG. 11 are an exploded perspective view of the electronic device 100 and show that the substrate 401 to be contained in an internal space between the case 201 and the cover 301 is provided in a prescribed location. The cover side positioning portion 302 is provided at one place at a central portion of an inner surface 301a of the cover 301 in a yz flat surface of the cover 301.

The case 201 is a substantially cuboid shape and is a hollow shape so that the substrate 401 on which electronic components 402a, 402b, 402c are packaged can be contained inside. As shown in FIG. 11, the case 201 has the substrate insertion opening portion 21 on one surface of the yz flat surface; and a slide groove 22 through which the substrate 401 is matched when the substrate 401 is inserted by sliding in the x axis direction from the substrate insertion opening portion 21 of the case 201 is provided along the x axis direction. The size in a z axis direction of the slide groove 22 is larger than the thickness of the substrate 401.

Two surfaces of sidewalls 201a, 201b of an xz flat surface of the case 201 near the substrate insertion opening portion 21 are each provided with the engagement convex portion 23. The engagement convex portion 23 fastens the case 201 and the cover 301 by fitting with the engagement concave portion 31a of the close-fitting piece 31 provided on the cover 301. A wedge shape, or a tapered shape such as a trapezoid, or a curved shape is included as an example of the shape of the engagement convex portion 23.

The case 201 is formed of material with high heat conductivity, for example, metal, heat conductive resin, or material in which metal plating is applied to heat conductive resin. Further, it is desirable to apply surface finishing, for example, alumite treatment or coating, which enhances a radiation rate, to the outside surface of the case 201.

The cover 301 is a substantially U shape that is such as to block the substrate insertion opening portion 21 of the case 201. Two surfaces of an xz flat surface of the cover 301 are each provided with the close-fitting piece 31 having the engagement concave portion 31a. It may be permissible if the shape of the engagement concave portion 31a of the close-fitting piece 31 is fitted with the engagement convex portion 23 provided on the sidewalls 201a, 201b of the case 201. The cover side positioning portion 302 is provided at one place in a yz flat surface of the cover 301 at a central portion of the inner surface 301a of the cover 301.

The inner surface 301a and an outer surface 301b of the yz flat surface of the cover 301 are a shape which is parallel to the yz flat surface or expanded in a crescent shape in a positive direction of the x axis in a state being not attached to the case 201. The cover 301 is formed of metal plate material, resin, rubber, or the like.

The substrate 401 is one in which a plurality of electronic components is packaged on a substantially rectangular base material. The size of an xy flat surface of the substrate 401 is substantially equivalent to the xy flat surface of the housing 101; and the electronic components 402a, 402b, 402c are packaged on an upper surface of the substrate 401 and an electronic component 402d is packaged on a lower surface of the substrate 401. Glass epoxy material, thermosetting resin, fluorine resin, metal material and the like are used by being combined on the base material.

An internal structure of the electronic device 100 will be described on the basis of FIG. 12 through FIG. 15. On both end portions of an innermost portion of the case 201, a case side positioning portion 204a is provided at one place on an innermost surface 201a most away from the cover 301 on the line B-B and a case side positioning portion 204b is provided at one more place at the position of an innermost surface 201c of the case 201 in symmetrical relation with respect to the line A1-A1. The shape of the case side positioning portion is common to the case side positioning portion 204a and the case side positioning portion 204b; thus, the description will be made using the case side positioning portion 204a.

The case side positioning portion 204a is composed of an upper side sandwiching body 205 and a lower side sandwiching body 206 which are protruded from the innermost surface 201a of the case 201 in the positive direction of the x axis. The case side positioning portion 204a is a spring shape in which the substrate 401 is fixed by being sandwiched; and in Embodiment 2, an example will be described on the basis of FIG. 14.

A cross section of an xz flat surface of an upper side sandwiching body 205 is a shape which is inclined in a negative direction of the z axis as it is away along the x axis from the innermost surface 201a of the case 201 and then inclined in a positive direction of the z axis. A cross section of an xz flat surface of the lower side sandwiching body 206 is a shape which is protruded substantially linearly along the x axis from the innermost surface 201a of the case 201 and is substantially parallel to the xy flat surface of the substrate 401. A top end portion of the substrate 401 is positioned in a space formed by the upper side sandwiching body 205 and the lower side sandwiching body 206; and the lower side sandwiching body 206 may be inclined so as to be widened on the entrance side when inserting so that the substrate 401 is easily inserted. The upper side sandwiching body 205 and the lower side sandwiching body 206 have a shape broad in a y axis direction.

The cover side positioning portion 302 is provided on the cover 301 at one place at a central portion on the line A1-A1. The cover side positioning portion 302 is composed of an upper side sandwiching body 303 and a lower side sandwiching body 304 which are protruded in the x axis direction from the inner surface 301a on the case 201 side in the yz flat surface of the cover 301. A rear end portion of the substrate 401 is positioned in a space formed by the upper side sandwiching body 303 and the lower side sandwiching body 304 and is a spring shape in which the substrate 401 is fixed by being sandwiched at the cover side positioning portion 302; and in Embodiment 2, an example will be described on the basis of FIG. 15.

A cross section of an xz flat surface of the upper side sandwiching body 303 is a shape which is inclined in a negative direction of the z axis as it is away along the x axis from the inner surface 301a of the cover 301 and then inclined in a positive direction of the z axis. A cross section of an xz flat surface of the lower side sandwiching body 304 is a shape which is protruded substantially linearly along the x axis from the inner surface 301a of the cover 301 and is substantially parallel to the xy flat surface of the substrate 401. The lower side sandwiching body 304 may be inclined so as to be widened on the entrance side when inserting so that the substrate 401 is easily inserted. The upper side sandwiching body 303 and the lower side sandwiching body 304 have a shape broad in the y axis direction.

A part of positioning the z axis direction in a thickness direction of the substrate 401 of the case side positioning portion 204a is the upper side sandwiching body 205 and the lower side sandwiching body 206; and a part of positioning the x axis direction in a direction perpendicular to the thickness of the substrate 401 of the case side positioning portion 204a is a base portion of the upper side sandwiching body 205 and a wall surface 203 of the yz flat surface which comes in contact with a base portion of the lower side sandwiching body 206.

The substrate 401 is inserted in the slide groove 22 and the top end portion of the substrate 401 is inserted between the upper side sandwiching body 205 and the lower side sandwiching body 206, whereby the z axis direction in the thickness direction of the substrate 401 is positioned. Then, a top end surface of the substrate 401 is brought into contact with the wall surface 203, whereby the x axis direction in the direction perpendicular to the thickness of the substrate 401 is positioned.

A part of positioning the z axis direction in the thickness direction of the substrate 401 of the cover side positioning portion 302 of the cover 301 is the upper side sandwiching body 303 and the lower side sandwiching body 304 which are provided in a protruding condition on the inner surface 301a of the cover 301; and a part of positioning the x axis direction in the direction perpendicular to the thickness of the substrate 401 of the cover side positioning portion 302 is a wall surface 305 of the inner surface 30a of the cover 30 which comes in contact with a base portion of the upper side sandwiching body 303 and a base portion of the lower side sandwiching body 304.

After the substrate 401 is inserted in the case 201, the engagement concave portion 31a of the close-fitting piece 31 provided on the cover 301 is engaged with the engagement convex portion 23 of the case 201 to block the substrate insertion opening portion 21 of the case 201, whereby the cover 301 is attached to the case 201. With this manner, the upper side sandwiching body 303 and the lower side sandwiching body 304 of the cover side positioning portion 302, which are provided in a protruding condition on the inner surface 301a of the cover 301, are inserted in the rear end portion of the substrate 401; thus, the z axis direction in the thickness direction of the substrate 401 is positioned. Then, the wall surface 305 of the inner surface 301a of the cover 301 is brought into contact with the rear end surface of the substrate 401 and thus the x axis direction in the direction perpendicular to the thickness of the substrate 401 is positioned.

An electronic component with a large amount of heat generation of the electronic components packaged on the substrate 401 is positioned in a range surrounded by a straight line 501a connecting the case side positioning portion 204a and the case side positioning portion 204b which are provided on the case 201, a straight line 501b connecting the case side positioning portion 204a and the cover side positioning portion 302 provided on the cover 301, and a straight line 501c connecting the case side positioning portion 204b and the cover side positioning portion 302, as shown in FIG. 16.

In Embodiment 2, four electronic components 402a, 402b, 402c, 402d with a large amount of heat generation are arranged in the range surrounded by the straight lines 501a, 501b, 501c; three electronic components 402a, 402b, 402c are packaged on one side surface of the substrate 401 and one electronic component 402d is packaged on the opposite side surface. A peripheral configuration of the electronic components 402a, 402b, 402c will be described using FIG. 13.

The electronic components are arranged in the order of approaching the cover 301, that is, the electronic component 402a, the electronic component 402b, and the electronic component 402c are arranged in the order of going toward the negative direction of the x axis. A convex portion 207a, a convex portion 207b, and a convex portion 207c are provided in the vicinity of the electronic component 402a, the electronic component 402b, and the electronic component 402c, respectively, so as to come close to the electronic component 402a, the electronic component 402b, and the electronic component 402c.

The shapes of the convex portion 207a, the convex portion 207b, and the convex portion 207c have a resemblance in shape to the electronic component 402a, the electronic component 402b, and the electronic component 402c in the xy flat surface, respectively, and their sizes are larger than the electronic component 402a, the electronic component 402b, and the electronic component 402c so as to be able to entirely cover the electronic components. The convex portion 207a is the highest in the height in the z axis direction of the convex portion 207a, 207b, 207c; and it becomes lower in the order of the convex portion 207b and the convex portion 207c.

In this manner, in Embodiment 2, the height of the convex portion 207a, the convex portion 207b, and the convex portion 207c which are provided in the case 201 for heat withdrawal becomes high as it goes toward an insertion direction of the substrate 401, that is, a positive direction of the x axis; whereby, when the substrate 401 is inserted, assembly can be performed without interfering with the convex portion 207a, the convex portion 207b, and the convex portion 207c with the substrate 401. Simultaneously, it becomes possible to secure a sufficient heat dissipation path by providing a structure in which the heating component comes close to the heat withdrawal portion as much as possible.

Furthermore, as shown in FIG. 13, the electronic component 402d is provided on the back surface of the substrate 401 and the convex portion 403 arranged in close proximity to the electronic component 402d is provided on the case 201. Further, a convex portion 404 is provided in close proximity to the back surface of the substrate 401 directly under the electronic component 402a with a large amount of heat generation. Embodiment 3.

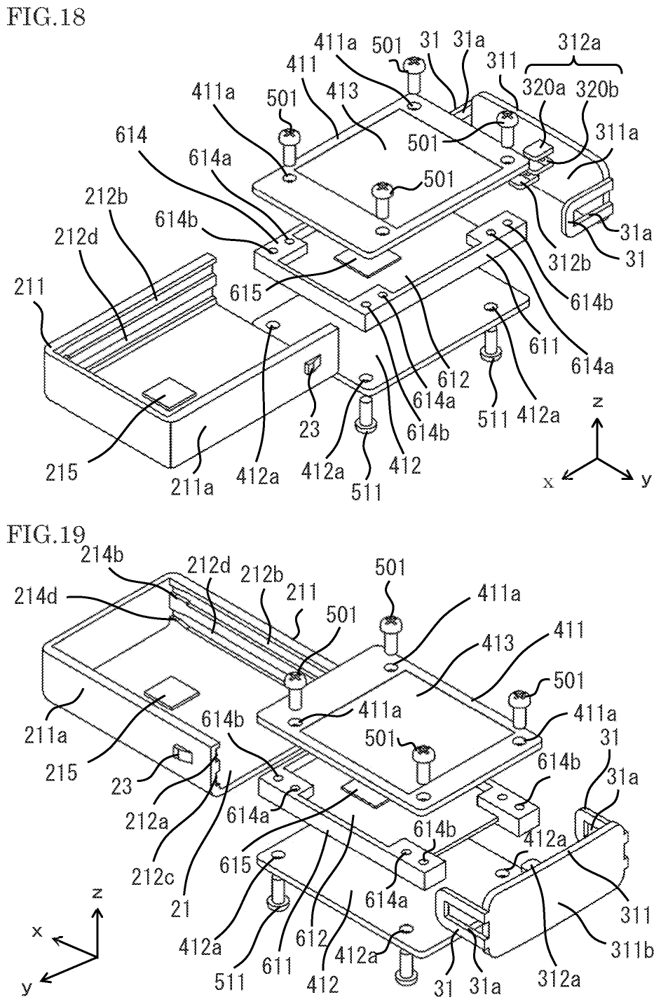

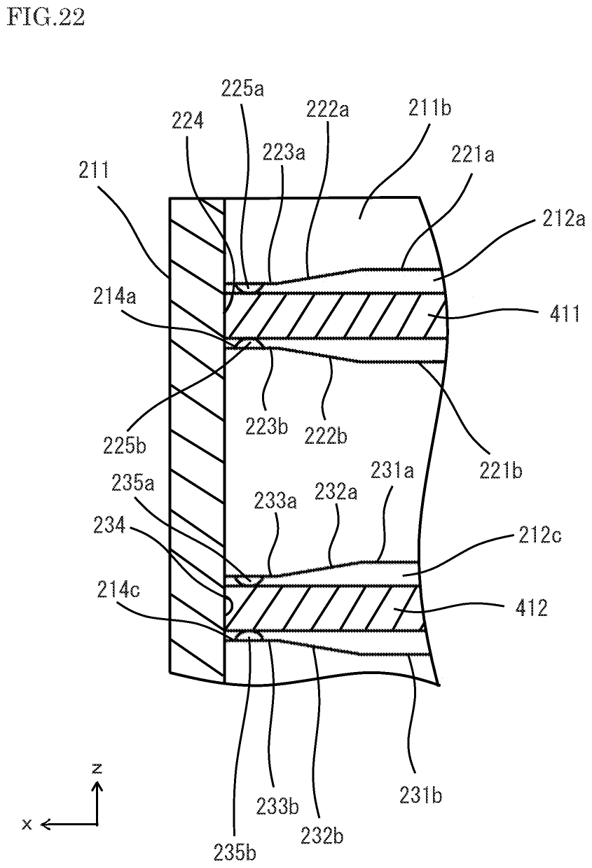

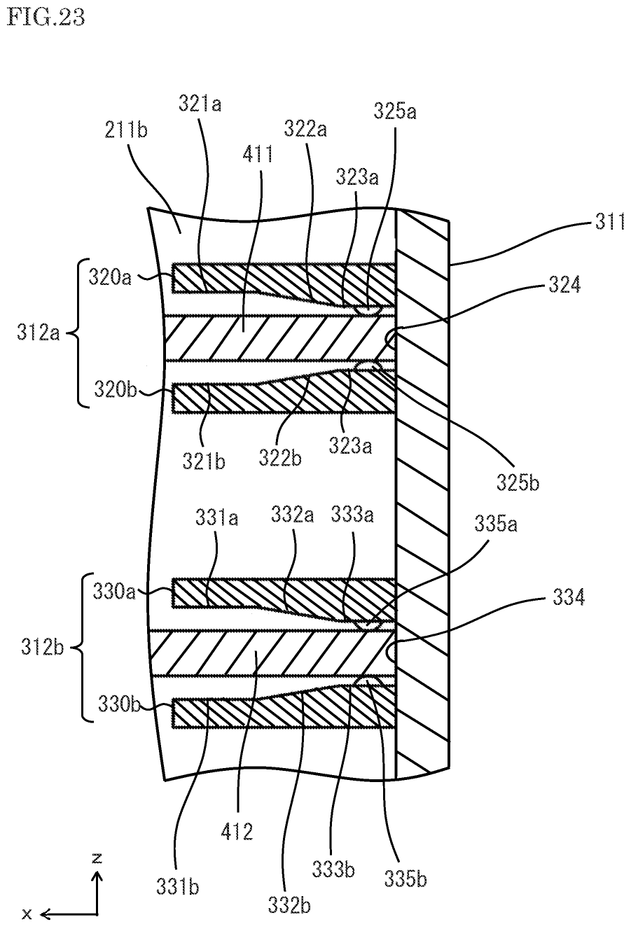

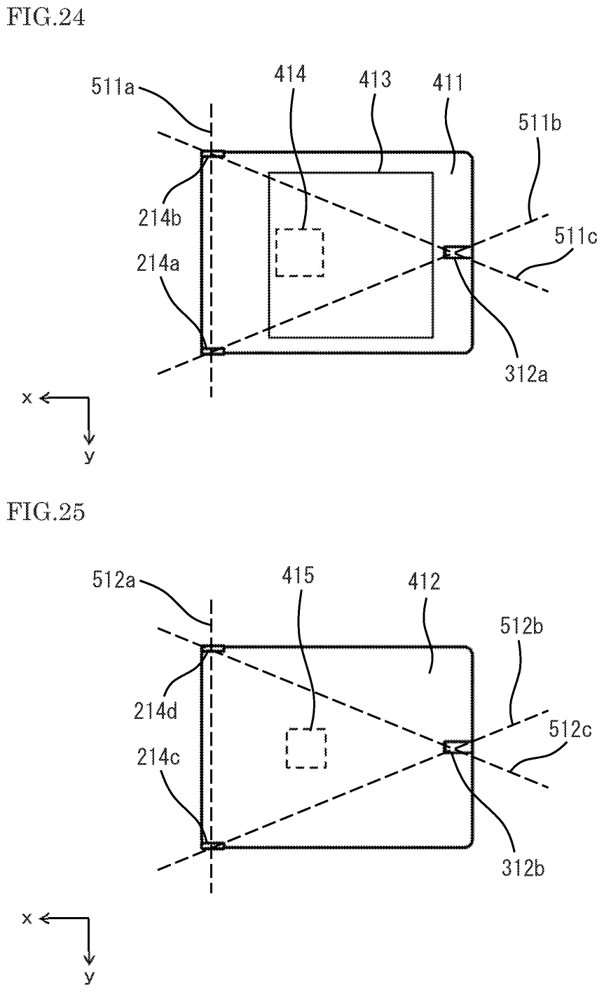

Embodiment 3 of the present application will be described on the basis of FIG. 17 to FIG. 25. Then, in each of the drawings, identical or equivalent members and parts will be described with the same reference numerals (and letters) assigned thereto. FIG. 17 is a perspective view showing an electronic device according to Embodiment 3. FIG. 18 is a perspective view showing a dismantled state of the electronic device according to Embodiment 3 and is the perspective view seen from a positive direction of an x axis. FIG. 19 is a perspective view showing a dismantled state of the electronic device according to Embodiment 3 and is the perspective view seen from a negative direction of the x axis. FIG. 20 is a plan view in an xy flat surface showing the electronic device according to Embodiment 3. FIG. 21 is a sectional view in the xz flat surface taken along the line A2-A2 of FIG. 20 showing the electronic device according to Embodiment 3. FIG. 22 is an enlarged sectional view in the xz flat surface taken along the line B2-B2 of FIG. 20 showing the electronic device according to Embodiment 3. FIG. 23 is an enlarged sectional view in the xz flat surface taken along the line C2-C2 of FIG. 20 showing the electronic device according to Embodiment 3. FIG. 24 is a plan view showing the arrangement of an electronic component in the electronic device according to Embodiment 3 and is a schematic view of the xy flat surface showing the arrangement of a heating component. FIG. 25 is a plan view showing the arrangement of an electronic component in the electronic device according to Embodiment 3 and is a schematic view of the xy flat surface showing the arrangement of a heating component.

In Embodiment 3 of the present application, the same reference numerals are given to portions common to Embodiment 1 and Embodiment 2 and their description will be omitted; and different points from Embodiment 1 and Embodiment 2 will be mainly described.

FIG. 17 is the perspective view of an electronic device 110 according to Embodiment 3 and shows a housing 111 in which a first substrate 411 and a second substrate 412, each of which having an expanse in the xy flat surface, are contained inside. The housing 111 is mainly composed of a case 211 in which the first substrate 411 and the second substrate 412 are inserted by sliding, and a cover 311 which is overlapped with the case 211 in an x axis direction and blocks a substrate insertion opening portion 21 in a yz flat surface of the case 211 for the first substrate 411 and the second substrate 412 which are mounted in the inside of the housing. An engagement convex portion 23 is provided on a sidewall of the case 211; and a close-fitting piece 31, which has an engagement concave portion 31a to be engaged with the engagement convex portion 23 of the case 211, is provided on the cover 311.

An opening portion 218 partially opened is provided in an upper surface of one surface on one side of the xy flat surface of the case 211. A surface on one side of the first substrate 411 is exposed from the opening portion 218; and a transmitting and receiving antenna module 413 as the electronic component is packaged on the first substrate 411 and is exposed to an outer surface of the case 211. A transmitting and receiving IC (Integrated Circuit) 414 as the electronic component is packaged on a back surface of the first substrate 411.

FIG. 18 and FIG. 19 are the exploded perspective view of the electronic device 110 and show that the first substrate 411 and the second substrate 412 which are to be contained in an internal space between the case 211 and the cover 311 are provided in a prescribed location and a relay member 611 is provided in a prescribed location between the first substrate 411 and the second substrate 412.

The case 211 is a hollow shape so that the first substrate 411 on which the transmitting and receiving antenna module 413 and the transmitting and receiving IC 414 are packaged and the second substrate 412 on which the electronic component 415 is packaged on the back surface can be contained inside. As shown in FIG. 19, the case 211 has the substrate insertion opening portion 21 on one surface of the yz flat surface; and first slide grooves 212a, 212b through which the first substrate 411 is matched when the first substrate 411 is inserted by sliding in the x axis direction from the substrate insertion opening portion 21 of the case 211 are provided along the x axis direction. The size in a z axis direction of the first slide grooves 212a, 212b is larger than the thickness of the first substrate 411. Furthermore, second slide grooves 212c, 212d through which the second substrate 412 is matched when the second substrate 412 is inserted by sliding in the x axis direction from the substrate insertion opening portion 21 of the case 211 are provided along the x axis direction. The size in the z axis direction of the second slide grooves 212c, 212d is larger than the thickness of the second substrate 412.

Two surfaces of sidewalls 211a, 211b of an xz flat surface of the case 211 near the substrate insertion opening portion 21 are each provided with the engagement convex portion 23. The engagement convex portion 23 fastens the case 211 and the cover 311 by fitting with the engagement concave portion 31a of the close-fitting piece 31 provided on the cover 311. A wedge shape, or a tapered shape such as a trapezoid, or a curved shape is included as an example of the shape of the engagement convex portion 23.

The case 211 is formed of material with high heat conductivity, for example, metal, heat conductive resin, or material in which metal plating is applied to heat conductive resin. Further, it is desirable to apply surface finishing, for example, alumite treatment or coating, which enhances a radiation rate, to the outside surface of the case 211.

Case side first positioning portions 214a, 214b are provided, respectively, on the case 211 at a position most away from the cover 311 on the first slide grooves 212a, 212b for positioning the first substrate 411. Furthermore, case side second positioning portions 214c, 214d are provided, respectively, on the case 211 at a position most away from the cover 311 on the second slide grooves 212c, 212d for positioning the second substrate 412. The case side positioning portions are each provided at a total of four places.

The shape of the case side positioning portion is common to the case side first positioning portions 214a, 214b and the case side second positioning portions 214c, 214d; thus, the description will be made using the case side first positioning portion 214a and the case side second positioning portion 214c on the basis of FIG. 22. The case side first positioning portion 214a includes: an inclined portion 222a and an inclined portion 222b which are inclined so that the width of the first slide groove 212a becomes narrow as an upper surface 221a and a lower surface 221b of an xy flat surface of the first slide groove 212a are away from the cover 311, respectively; a case side first plane portion 223a and a case side second plane portion 223b which are connected, respectively, to the inclined portion 222a and the inclined portion 222b and are extended parallel to the xy flat surface in a direction away from the cover 311; and a case side first projection body 225a and a case side second projection body 225b which are provided so as to partially narrow a gap formed by a wall surface 224 of the yz flat surface which comes in contact with the case side first plane portion 223a and the case side second plane portion 223b, the case side first plane portion 223a, and the case side second plane portion 223b. The size of a gap in the z axis direction which is formed by the case side first projection body 225a and the case side second projection body 225b is equivalent to or smaller than the thickness of the first substrate 411.

The case side second positioning portion 214c includes: an inclined portion 232a and an inclined portion 232b which are inclined so that the width of the second slide groove 212c becomes narrow as an upper surface 231a and a lower surface 231b of an xy flat surface of the second slide groove 212c are away from the cover 311, respectively; a case side third plane portion 233a and a case side fourth plane portion 233b which are connected, respectively, to the inclined portion 232a and the inclined portion 232b and are extended parallel to an xy flat surface in a direction away from the cover 311; and a case side third projection body 235a and a case side fourth projection body 235b which are provided so as to partially narrow a gap formed by a wall surface 234 of the yz flat surface which comes in contact with the case side third plane portion 233a and the case side fourth plane portion 233b, the case side third plane portion 233a, and the case side fourth plane portion 233b. The size of a gap in the z axis direction which is formed by the case side third projection body 235a and the case side fourth projection body 235b is equivalent to or smaller than the thickness of the second substrate 412.

A part of positioning a z axis direction in a thickness direction of the first substrate 411 of the case side first positioning portion 214a is the case side first plane portion 223a, the case side second plane portion 223b, the case side first projection body 225a, and the case side second projection body 225b; and a part of positioning an x axis direction in a direction perpendicular to the thickness of the first substrate 411 of the case side first positioning portion 214a is the wall surface 224 of the yz flat surface which comes in contact with the case side first plane portion 223a and the case side second plane portion 223b.

The first substrate 411 is inserted in the first slide groove 212a and the first slide groove 212b, and a top end portion of the first substrate 411 passes through the inclined portion 222a and the inclined portion 222b and is inserted between the case side first projection body 225a and the case side second projection body 225b, whereby the z axis direction in the thickness direction of the first t substrate 411 is positioned. Then, a top end surface of the first substrate 411 is brought into contact with the wall surface 224, whereby the x axis direction in the direction perpendicular to the thickness of the first substrate 411 is positioned.

A part of positioning a z axis direction in a thickness direction of the second substrate 412 of the case side second positioning portion 214c is the case side third plane portion 233a, the case side fourth plane portion 233b, the case side third projection body 235a, and the case side fourth projection body 235b; and a part of positioning an x axis direction in a direction perpendicular to the thickness of the second substrate 412 of the case side second positioning portion 214c is the wall surface 234 of the yz flat surface which comes in contact with the case side third plane portion 233a and the case side fourth plane portion 233b.

The second substrate 412 is inserted in the second slide groove 212c and the second slide groove 212d; and a top end portion of the second substrate 412 passes through the inclined portion 232a and the inclined portion 232b and is inserted between the case side third projection body 235a and the case side fourth projection body 235b, whereby the z axis direction in the thickness direction of the second substrate 412 is positioned. Then, a top end surface of the second substrate 412 is brought into contact with the wall surface 234, whereby the x axis direction in the direction perpendicular to the thickness of the second substrate 412 is positioned.

As described above, the description has been made on the case side first positioning portion 214a and the case side second positioning portion 214c, however, although not shown in the drawing, the case side first positioning portion 214b and the case side second positioning portion 214d are also the same configuration.

A cover side first positioning portion 312a of the cover 311 is provided at one place at a position shifted to a positive direction of a y axis from a substantially center line of a yz flat surface of the cover 311; and a cover side second positioning portion 312b is provided at one place at a position shifted to a negative direction of the y axis from the substantially center line of the yz flat surface of the cover 311. More specifically, provisions are made for corresponding to the first substrate 411 and the second substrate 412 at upper and lower places (a total of two places) of the y axis. The shape of the cover side positioning portion is common to the cover side first positioning portion 312a and the cover side second positioning portion 312b and its configuration will be described on the basis of FIG. 23.

The cover side first positioning portion 312a corresponding to the first substrate 411 and the cover side second positioning portion 312b corresponding to the second substrate 412 are provided at two places at positions different in height in the z axis direction on a central portion of an inner surface 311a of the cover 311 of the yz flat surface of the cover 311.

The cover side first positioning portion 312a is composed of a first sandwiching piece 320a and a second sandwiching piece 320b which are protruded in a positive direction of the x axis from the inner surface 311a of the cover 311 on the case 211 side of the yz flat surface of the cover 311. Surfaces sandwiched by the first sandwiching piece 320a and the second sandwiching piece 320b include: a lower surface side plane portion 321a and an upper surface side plane portion 321b, respectively, which are extended parallel to the xy flat surface in a direction of the inner surface 311a of the cover 311; an inclined portion 322a and an inclined portion 322b, respectively, which are inclined to the first substrate 411 side as it goes toward the inner surface 311a of the cover 311; a cover side first plane portion 323a and a cover side second plane portion 323b, respectively, which are connected to the inclined portion 322a and the inclined portion 322b and are extended parallel to the xy flat surface in the direction of the inner surface 311a of the cover 311; and a cover side first projection body 325a and a cover side second projection body 325b, respectively, which are provided so as to partially narrow a gap formed by a wall surface 324 of the yz flat surface which comes in contact with the cover side first plane portion 323a and the cover side second plane portion 323b, the cover side first plane portion 323a, and the cover side second plane portion 323b. The size of a gap in the z axis direction which is formed by the cover side first projection body 325a and the cover side second projection body 325b is equivalent to or smaller than the thickness of the first substrate 411.

The cover side second positioning portion 312b is composed of a third sandwiching piece 330a and a fourth sandwiching piece 330b which are protruded in the positive direction of the x axis from the inner surface 311a of the cover 311 on the case 211 side of the yz flat surface of the cover 311. Surfaces sandwiched by the third sandwiching piece 330a and the fourth sandwiching piece 330b include: a lower surface side plane portion 331a and an upper surface side plane portion 331b respectively, which are extended parallel to the xy flat surface in the direction of the inner surface 311a of the cover 311; an inclined portion 332a and an inclined portion 332b, respectively, which are inclined to the second substrate 412 side as it goes toward the inner surface 311a of the cover 311; a cover side third plane portion 333a and a cover side fourth plane portion 333b, respectively, which are connected to the inclined portion 332a and the inclined portion 332b and are extended parallel to the xy flat surface in the direction of the inner surface 311a of the cover 311; and a cover side third projection body 335a and a cover side fourth projection body 335b, respectively, which are provided so as to partially narrow a gap formed by the wall surface 334 of the yz flat surface which comes in contact with the cover side third plane portion 333a and the cover side fourth plane portion 333b, the cover side third plane portion 333a, and the cover side fourth plane portion 333b. The size of a gap in the z axis direction which is formed by the cover side third projection body 335a and the cover side fourth projection body 335b is equivalent to or smaller than the thickness of the second substrate 412.

A part of positioning the z axis direction in the thickness direction of the first substrate 411 of the cover side first positioning portion 312a is the inclined portion 322a of the first sandwiching piece 320a and the inclined portion 322b of the second sandwiching piece 320b which are provided in a protruding condition on the inner surface 311a of the cover 311, the cover side first projection body 325a, and the cover side second projection body 325b; and a part of positioning the x axis direction in the direction perpendicular to the thickness of the first substrate 411 of the cover side first positioning portion 312a is the wall surface 324 of the inner surface 311a of the cover 311 which comes in contact with the cover side first plane portion 323a of the first sandwiching piece 320a and the cover side second plane portion 323b of the second sandwiching piece 320b.

After the first substrate 411 is inserted in the case 211, the engagement concave portion 31a of the close-fitting piece 31 provided on the cover 311 is engaged with the engagement convex portion 23 of the case 211 to block the substrate insertion opening portion 21 of the case 211, whereby the cover 311 is attached to the case 211. With this manner, a rear end portion of the first substrate 411 passes through the inclined portion 322a of the first sandwiching piece 320a and the inclined portion 322b of the second sandwiching piece 320b of the cover side first positioning portion 312a which are provided in a protruding condition on the inner surface 311a of the cover 311 and is inserted between the cover side first projection body 325a and the cover side second projection body 325b; thus, the z axis direction in the thickness direction of the first substrate 411 is positioned. Then, the wall surface 324 of the inner surface 311a of the cover 311 is brought into contact with a rear end surface of the first substrate 411 and thus the x axis direction in the direction perpendicular to the thickness of the first substrate 411 is positioned.

A part of positioning the z axis direction in the thickness direction of the second substrate 412 of the cover side second positioning portion 312b is the inclined portion 332a of the third sandwiching piece 330a and the inclined portion 332b of the fourth sandwiching piece 330b which are provided in a protruding condition on the inner surface 311a of the cover 311, the cover side third projection body 335a, and the cover side fourth projection body 335b; and a part of positioning the x axis direction in the direction perpendicular to the thickness of the second substrate 412 of the cover side second positioning portion 312b is the wall surface 334 of the inner surface 311a of the cover 311 which comes in contact with the cover side third plane portion 333a of the third sandwiching piece 330a and the cover side fourth plane portion 333b of the fourth sandwiching piece 330b.

After the second substrate 412 is inserted in the case 211, the engagement concave portion 31a of the close-fitting piece 31 provided on the cover 311 is engaged with the engagement convex portion 23 of the case 211 to block the substrate insertion opening portion 21 of the case 211, whereby the cover 311 is attached to the case 211. With this manner, a rear end portion of the second substrate 412 passes through the inclined portion 332a of the third sandwiching piece 330a and the inclined portion 332b of the fourth sandwiching piece 330b of the cover side second positioning portion 312b which are provided in a protruding condition on the inner surface 311a of the cover 311 and is inserted between the cover side third projection body 335a and the cover side fourth projection body 335b; thus, the z axis direction in the thickness direction of the second substrate 412 is positioned. Then, the wall surface 334 of the inner surface 311a of the cover 311 is brought into contact with a rear end surface of the second substrate 412 and thus the x axis direction in the direction perpendicular to the thickness of the second substrate 412 is positioned.

The transmitting and receiving antenna module 413 as the electronic component is packaged on one side surface of the first substrate 411. As an antenna system, for example, a micro strip antenna, a waveguide slot antenna, or the like can be applied. The transmitting and receiving antenna module 413 including a transmitting and receiving antenna or the like as the electronic component serving as an antenna formation portion, and the transmitting and receiving IC 414 may be packaged on the same surface of the first substrate 411 or may be packaged on both surfaces (one main surface and back surface) of the first substrate 411.

When the transmitting and receiving antenna module 413 and the transmitting and receiving IC 414 are packaged on the same surface, it is desirable that the attaching opening portion 218 provided on the case 211 is set to a minimum size, which is only a range where a radio wave generated from the transmitting and receiving antenna of the transmitting and receiving antenna module 413 is not blocked, and the transmitting and receiving IC 414 is covered with the case 211 and is provided with a convex portion from the case 211 toward the transmitting and receiving IC 414.

In Embodiment 3, the description will be made on the case where the transmitting and receiving IC 414 with a large amount of heat generation is packaged on the surface (back surface) different from the packaging surface of the transmitting and receiving antenna module 413. As shown in FIG. 24, the transmitting and receiving IC 414 is positioned in a range surrounded by a straight line 511a connecting the case side first positioning portion 214a and the case side first positioning portion 214b which are provided on the case 211, a straight line 511b connecting the case side first positioning portion 214a and the cover side first positioning portion 312a provided on the cover 311, and a straight line 511c connecting the case side first positioning portion 214b and the cover side first positioning portion 312a.

Of the packaged electronic components, the electronic component 415 with a large amount of heat generation is packaged on the second substrate 412. As shown in FIG. 25, the electronic component 415 is positioned in a range surrounded by a straight line 512a connecting the case side second positioning portion 214c and the case side second positioning portion 214d which are provided on the case 211, a straight line 512b connecting the case side second positioning portion 214c and the cover side second positioning portion 312b provided on the cover 311, and a straight line 512c connecting the case side second positioning portion 214d and the cover side second positioning portion 312b.

The first substrate 411 and the second substrate 412 connect between the substrates using a substrate-to-substrate connector, a connector for FPC (Flexible Printed Circuit)/FFC (Flexible Flat Cable), or the like (not shown in the drawing).

A relay member 611 is a substantially cuboid shape and is provided with a concave portion 612 and a concave portion 613 on both surfaces of the xy flat surface. The concave portion 612 is provided to avoid interference with the electronic component 414 packaged on the first substrate 411; and the concave portion 613 is provided to avoid interference with the electronic component 415 packaged on the second substrate 412. Furthermore, the relay member 611 is provided with attaching portions 614 at four places, the attaching portion 614 being for fixing the first substrate 411 and the second substrate 412 to the relay member 611. The relay member 611 is formed of material with high heat conductivity, for example, metal, heat conductive resin, or material in which metal plating is applied to heat conductive resin.

In Embodiment 3, the attaching portions 614 of the relay member 611 are provided with attaching portions 614a for attaching the first substrate 411 at four places and are provided with attaching portions 614b for attaching the second substrate 412 at four places. This Embodiment 3 shows the case where the attaching portion 614a and the attaching portion 614b are each constituted by a threaded hole.

The first substrate 411 is formed with a through hole 411a in which a screw 501 is inserted into the attaching portion 614a; and the second substrate 412 is formed with a through hole 412a in which a screw 511 is inserted into the attaching portion 614b.

The first substrate 411, the relay member 611, and the second substrate 412 are overlapped, the screw 501 is inserted into the through hole 411a of the first substrate 411 to be screwed to the attaching portion 614a of the relay member 611, and the screw 511 is inserted into the through hole 412a of the second substrate 412 to be screwed to the attaching portion 614b of the relay member 611, whereby the first substrate 411, the relay member 611, and the second substrate 412 are formed into an integral configuration.

This Embodiment 3 describes the case where the attaching portion 614a and the attaching portion 614b of the relay member 611 are each constituted by the threaded hole and attached by the screw 501 and the screw 511, but the present application is not limited to this; and even when the attaching portion 614a and the attaching portion 614b of the relay member 611 are each constituted by an engagement hole and a convex shape, a positioning pin, a snap fit, or the like which is engaged with the engagement holes of the attaching portion 614a and the attaching portion 614b of the relay member 611 without using the screw 501 and the screw 511, the same effects can be exhibited.

A peripheral configuration of the transmitting and receiving IC 414 packaged on the first substrate 411 and the electronic component 415 packaged on the second substrate 412 will be described using FIG. 21. A convex portion 615 is provided in the vicinity of the transmitting and receiving IC 414 so as to come close to the transmitting and receiving IC 414 from the relay member 611. A convex portion 215 is provided in the vicinity of the electronic component 415 so as to come close to the electronic component 415 from the case 211. A convex portion 616 is provided so as to come close to the second substrate 412a, in which the electronic component 415 is packaged, from the relay member 611.

The shape of the convex portion 615 of the relay member 611 has a resemblance in shape to the transmitting and receiving IC 414 in the xy flat surface and is larger than the transmitting and receiving IC 414 so as to be able to entirely cover the transmitting and receiving IC 414. The shape of the convex portion 215 of the case 211 and that of the convex portion 616 of the relay member 611 have each a resemblance in shape to the electronic component 415 in the xy flat surface and are larger than the electronic component 415 so as to be able to entirely cover the electronic component 415.

An assembly method of the electronic device 110 will be described. The first substrate 411 is fixed to the attaching portion 614a of the relay member 611 with the screw 501; and the second substrate 412 is fixed to the attaching portion 614b of the relay member 611 with the screw 511. In this manner, the first substrate 411, the relay member 611, and the second substrate 412 are formed into an integrally configured body.

The thickness direction of the first substrate 411 is oriented to the first slide groove 212a and the first slide groove 212b of the case 211, the thickness direction of the second substrate 412 is oriented to the second slide groove 212c and the second slide groove 212d of the case 211, and the first substrate 411 is slid in the x axis direction along the first slide groove 212a and the first slide groove 212b and the second substrate 412 is slid in the x axis direction along the second slide groove 212c and the second slide groove 212d simultaneously to insert the first substrate 411 and the second substrate 412 in the case 211.

With this manner, the entirety of the relay member 611 in which the first substrate 411 and the second substrate 412 are fixed can be provided in a prescribed location in the case 211. After the first substrate 411 and the second substrate 412 are provided in a prescribed location in the case 211, the engagement concave portion 31a of the close-fitting piece 31 provided on the cover 311 is engaged with the engagement convex portion 23 of the case 211, whereby the cover 311 is attached to the case 211.

When the cover 311 is attached to the case 211, the first substrate 411 is pressed by the cover 311 in the x axis direction until the top end surface of the first substrate 411 comes in contact with the wall surface 224 of the case side first positioning portion 214a and the case side first positioning portion 214b of the case 211; and the inner surface 311a and an outer surface 311b of the cover 311 become a shape which is expanded in a crescent shape in a negative direction of the x axis or parallel to the yz flat surface. With this manner, the position of the axis direction of the first substrate 411 is determined.

The first substrate 411 is sandwiched by the gap surrounded by the case side first projection body 225a and the case side second projection body 225b of the case side first positioning portion 214a and the case side first positioning portion 214b of the case 211, and by the gap surrounded by the cover side first projection body 325a and the cover side second projection body 325b of the cover side first positioning portion 312a of the cover 311; thus, the position in the z axis direction is determined.

Similarly, also in the second substrate 412, when the cover 311 is attached to the case 211, the second substrate 412 is pressed by the cover 311 in the x axis direction until the top end surface of the second substrate 412 comes in contact with the wall surface 224 of the of the case side second positioning portion 214c and the case side second positioning portion 214d of the case 211; and the inner surface 311a and the outer surface 311b of the cover 311 become a shape which is expanded in a crescent shape in the negative direction of the x axis or parallel to the yz flat surface. With this manner, the position of the x axis direction of the second substrate 412 is determined.

The second substrate 412 is sandwiched by the gap surrounded by the case side third projection body 235a and the case side fourth projection body 235b of the case side second positioning portion 214c and the case side second positioning portion 214d of the case 211, and by the gap surrounded by the cover side third projection body 335a and the cover side fourth projection body 335b of the cover side second positioning portion 312b of the cover 311; thus, the position in the z axis direction is determined.

It may be permissible in a state where a positional relationship of the first substrate 411, the second substrate 412, and the relay member 611 is not fixed so as to be uniquely determined, but is temporarily fixed; and it may be configured so that a positional relationship of the first substrate 411, the second substrate 412, and the case 211 is uniquely determined when the first substrate 411 and the second substrate 412 are provided in a prescribed location in the inside of the case 211 and then attached to the case side first positioning portions 214a, 214b and the case side second positioning portions 214c, 214d of the case 211, and the cover side first positioning portion 312a and the cover side second positioning portion 312b of the cover 311.

In this manner, in Embodiment 3, the first substrate 411 and the second substrate 412 can be attached by insertion in the housing 111 without using other fixing member such as a screw and assembly man-hours can be reduced.

Furthermore, the transmitting and receiving IC 414 with a large amount of heat generation is arranged in the range surrounded by the case side first positioning portion 214a and the case side first positioning portion 214b of the case 211 and the cover side first positioning portion 312a of the cover 311, whereby the transmitting and receiving IC 414 with a large amount of heat generation can be arranged at a position good for positional accuracy within the first substrate 411.

Similarly, also in the case of the second substrate 412, the electronic component 415 with a large amount of heat generation is arranged in the range surrounded by the case side second positioning portion 214c and the case side second positioning portion 214d of the case 211 and the cover side second positioning portion 312b of the cover 311, whereby the electronic component 415 with a large amount of heat generation can be arranged at a position good for positional accuracy within the second substrate 412. If positional accuracy of the electronic component 415 with a large amount of heat generation can be improved, it becomes possible to suppress variation of a gap between the electronic component 415 with a large amount of heat generation and the case 211 and a gap between the second substrate 412 on which the electronic component 415 is packaged and the relay member 611 and these can be come close.

With this manner, a gap between the convex portion 215 provided on the case 211 and the electronic component 415 and a gap between the convex portion 616 provided on the relay member 611 and the second substrate 412 can be reduced and it becomes possible to secure a sufficient heat dissipation path without filling a member with high heat conductivity between a heat generation member and a heat dissipation member.

In the positioning portions provided on the case or the cover, it may be formed integrally with the case or the cover, or one which is made of a different member may be combined by insert molding, adhesion, or the like.

In a method of fixing the case or the cover, it may be fixed using a snap fit or the like, or it may be fixed by adhesion, caulking, welding, or the like.

The present application describes various exemplified embodiments and examples; however, various features, aspects, and functions described in one or a plurality of embodiments are not limited to specific embodiments, but are applicable to embodiments individually or in various combinations thereof. Therefore, countless modified examples not exemplified are assumed in technical ranges disclosed in the specification of the present application. For example, there include: a case in which at least one constitutional element is modified; a case, added; or a case, omitted; and a case in which at least one constitutional element is extracted to combine with constitutional elements of other embodiments. Hereinafter, aspects of the present disclosure will be described together as supplementary notes.

### Supplementary Note 1

An electronic device comprising:
a substrate on which an electronic component is packaged;
a case in which a substrate insertion opening portion is provided, a slide groove through which the substrate is inserted by sliding is formed on both sidewalls, and the substrate is contained by being inserted in the slide groove from the substrate insertion opening portion; and
a cover which is coupled to the case to block the substrate insertion opening portion of the case,
wherein the case is provided with a case side positioning portion which has a part of positioning a thickness direction of the substrate and a part of positioning a direction perpendicular to the thickness of the substrate; and
the cover is provided with a cover side positioning portion which has a part of positioning the thickness direction of the substrate and a part of positioning the direction perpendicular to the thickness of the substrate.

### Supplementary Note 2

The electronic device according to the supplementary note 1,
wherein the case side positioning portion is provided on an innermost portion of a sidewall on one side of the case; and
wherein the cover side positioning portion is provided on the cover positioned on a diagonal of the case side positioning portion.

### Supplementary Note 3

The electronic device according to the supplementary note 2,
wherein the electronic component is arranged on a line connecting the case side positioning portion and the cover side positioning portion.

### Supplementary Note 4

The electronic device according to any one of the supplementary note 1 to the supplementary note 3,
wherein the case side positioning portion has an inclined portion by which a gap of the slide groove on the case side is formed into a gap smaller than other part; and
wherein the cover side positioning portion is composed of a first sandwiching piece and a second sandwiching piece which are arranged on an inner surface of the cover, are protruded to the case side, and are faced via the substrate,
the first sandwiching piece having an inclined portion inclined to the substrate side from a lower surface side plane portion of a protruding end portion of the first sandwiching piece toward the inner surface of the cover, and
the second sandwiching piece having an inclined portion inclined to the substrate side from an upper surface side plane portion of a protruding end portion of the second sandwiching piece toward the inner surface of the cover.

### Supplementary Note 5

The electronic device according to the supplementary note 1,
wherein the case side positioning portion is provided in a protruding condition on both end sides of an innermost wall of the case and is composed of sandwiching bodies sandwiching the substrate by elastic force; and
wherein the cover side positioning portion is arranged on a central portion of an inner surface of the cover and is composed of sandwiching bodies sandwiching the substrate by elastic force.

### Supplementary Note 6

The electronic device according to the supplementary note 2,
wherein the electronic component is arranged in a range of a line connecting the case side positioning portion on one side and the case side positioning portion on the other side, a line connecting the case side positioning portion on one side and the cover side positioning portion, and a line connecting the case side positioning portion on the other side and the cover side positioning portion.

### Supplementary Note 7

The electronic device according to any one of the supplementary note 1 to the supplementary note 6,
wherein the case has a convex portion provided in a protruding condition at least at a position of the electronic component.

### Supplementary Note 8

The electronic device according to the supplementary note 7,
wherein the convex portion is provided with a through hole that passes through a surface of the case, and
a heat dissipation material is filled in the through hole and between the convex portion and the electronic component.

### Supplementary Note 9

The electronic device according to any one of the supplementary note 1 to the supplementary note 8,
wherein the case has a convex portion provided in a protruding condition at a position directly under the electronic component.

### Supplementary Note 10

The electronic device according to the supplementary note 8,
wherein the convex portion provided on the case is that a height on an innermost wall side of the case is higher than a height on the cover side along an insertion direction of the substrate.

### Supplementary Note 11

The electronic device according to any one of the supplementary note 1 to the supplementary note 10,
wherein a fin is provided on the outside of the case.

### Supplementary Note 12

An electronic device comprising:
a first substrate on which an electronic component is packaged;
a second substrate on which an electronic component is packaged;
a case in which a substrate insertion opening portion and an attaching opening portion are provided, a first slide groove through which the first substrate is inserted by sliding and a second slide groove through which the second substrate is inserted by sliding are formed on both sidewalls, the first substrate is contained by being inserted in the first slide groove from the substrate insertion opening portion, and the second substrate is contained by being inserted in the second slide groove from the substrate insertion opening portion; and
a cover which is coupled to the case to block the substrate insertion opening portion of the case,
wherein the case is provided with a case side first positioning portion which has a part of positioning a thickness direction of the first substrate and a part of positioning a direction perpendicular to a thickness of the first substrate and a case side second positioning portion which has a part of positioning a thickness direction of the second substrate and a part of positioning a direction perpendicular to a thickness of the second substrate;
the cover is provided with a cover side first positioning portion which has a part of positioning the thickness direction of the first substrate and a part of positioning the direction perpendicular to the thickness of the first substrate and a cover side second positioning portion which has a part of positioning the thickness direction of the second substrate and a part of positioning the direction perpendicular to the thickness of the second substrate; and
a relay member connecting the first substrate and the second substrate is provided between the first substrate and the second substrate.

### Supplementary Note 13

The electronic device according to the supplementary note 12,
wherein the relay member is provided with a convex portion at a position facing the first substrate and a convex portion at a position facing the second substrate.

### Supplementary Note 14

The electronic device according to the supplementary note 12 or the supplementary note 13,
wherein the first substrate is exposed to the outside of the case.

### Supplementary Note 15

The electronic device according to any one of the supplementary note 12 to the supplementary note 14,
wherein the case side first positioning portion is provided on both end sides of an innermost wall of the case, the case side first positioning portion including:
an inclined portion inclined from an upper surface of the first slide groove on the case side toward the first substrate and an inclined portion inclined from a lower surface of the first slide groove on the case side toward the first substrate,
a case side first plane portion going from an end portion on the first substrate side of the inclined portion on the upper surface side of the first slide groove toward an innermost portion on the case side,
a case side first projection body arranged between the first substrate and the case side first plane portion,
a case side second plane portion going from an end portion on the first substrate side of the inclined portion on the lower surface side of the first slide groove toward the innermost portion on the case side, and
a case side second projection body arranged between the first substrate and the case side second plane portion;
wherein the case side second positioning portion is provided on both end sides of the innermost wall of the case, the case side second positioning portion including:
an inclined portion inclined from an upper surface of the second slide groove on the case side toward the second substrate and an inclined portion inclined from a lower surface of the second slide groove on the case side toward the second substrate,
a case side third plane portion going from an end portion on the second substrate side of the inclined portion on the upper surface side of the second slide groove toward an innermost portion on the case side,
a case side third projection body which is arranged between the second substrate and the case side third plane portion and sandwiches the second substrate,
a case side fourth plane portion going from an end portion on the second substrate side of the inclined portion on the lower surface side of the second slide groove toward the innermost portion on the case side, and
a case side fourth projection body which is arranged between the second substrate and the case side fourth plane portion and sandwiches the second substrate;
wherein the cover side first positioning portion is arranged on a central portion of an inner surface of the cover and is composed of a first sandwiching piece and a second sandwiching piece which are protruded to the case side and face each other via the first substrate, the cover side first positioning portion including:
an inclined portion inclined to the first substrate side from a lower surface side plane portion of a protruding end portion of the first sandwiching piece toward an inner surface of the cover,
a cover side first plane portion going from an end portion on the first substrate side of the inclined portion toward the inner surface of the cover,
a cover side first projection body which is arranged between the first substrate and the cover side first plane portion and sandwiches the first substrate,
an inclined portion inclined to the first substrate side from an upper surface side plane portion of a protruding end portion of the second sandwiching piece toward the inner surface of the cover,
a cover side second plane portion going from an end portion on the first substrate side of the inclined portion toward the inner surface of the cover, and
a cover side second projection body which is arranged between the first substrate and the cover side second plane portion and sandwiches the first substrate; and
wherein the cover side second positioning portion is arranged on a central portion of an inner surface of the cover and is composed of a third sandwiching piece and a fourth sandwiching piece which are protruded to the case side and face each other via the second substrate, the cover side second positioning portion including:
an inclined portion inclined to the second substrate side from a lower surface side plane portion of a protruding end portion of the third sandwiching piece toward the inner surface of the cover,
a cover side third plane portion going from an end portion on the second substrate side of the inclined portion toward the inner surface of the cover,
a cover side third projection body which is arranged between the first substrate and the cover side third plane portion and sandwiches the second substrate,
an inclined portion inclined to the second substrate side from a lower surface side plane portion of a protruding end portion of the third sandwiching piece toward the inner surface of the cover,
a cover side fourth plane portion going from an end portion on the second substrate side of the inclined portion toward the inner surface of the cover, and
a cover side fourth projection body which is arranged between the first substrate and the cover side fourth plane portion and sandwiches the second substrate.

### Supplementary Note 16

The electronic device according to any one of the supplementary note 12 to the supplementary note 15,
wherein the electronic component packaged on the first substrate is arranged in a range of a line connecting the case side first positioning portion on one side and the case side first positioning portion on the other side, a line connecting the case side first positioning portion on one side and the cover side first positioning portion, and a line connecting the case side first positioning portion on the other side and the cover side first positioning portion; and
wherein the electronic component packaged on the second substrate is arranged in a range of a line connecting the case side second positioning portion on one side and the case side second positioning portion on the other side, a line connecting the case side second positioning portion on one side and the cover side second positioning portion, and a line connecting the case side second positioning portion on the other side and the cover side second positioning portion.

### Supplementary Note 17

The electronic device according to any one of the supplementary note 12 to the supplementary note 16,
wherein the relay member is provided with a first fastening portion which fastens and fixes the first substrate and a second fastening portion which fastens and fixes the second substrate.

The present application is suitable for actualizing an electronic device capable of securing a sufficient heat dissipation path while reducing assembly man-hours.

Various modifications and alternations of this application will be apparent to those skilled in the art without departing from the scope and spirit of this application, and it should be understood that this is not limited to the illustrative embodiments set forth herein.

What is claimed is:

1. An electronic device comprising:
a substrate on which an electronic component is packaged;
a case in which a substrate insertion opening portion is provided, a slide groove through which the substrate is inserted by sliding is formed on both sidewalls, and the substrate is contained by being inserted in the slide groove from the substrate insertion opening portion; and
a cover which is coupled to the case to block the substrate insertion opening portion of the case,
wherein the case is provided with a case side positioning portion which has a part of positioning a thickness direction of the substrate and a part of positioning a direction perpendicular to the thickness of the substrate; and
the cover is provided with a cover side positioning portion which has a part of positioning the thickness direction of the substrate and a part of positioning the direction perpendicular to the thickness of the substrate.

2. The electronic device according to claim 1,
wherein the case side positioning portion is provided on an innermost portion of a sidewall on one side of the case; and
wherein the cover side positioning portion is provided on the cover positioned on a diagonal of the case side positioning portion.

3. The electronic device according to claim 2,
wherein the electronic component is arranged on a line connecting the case side positioning portion and the cover side positioning portion.

4. The electronic device according to claim 1,
wherein the case side positioning portion has an inclined portion by which a gap of the slide groove on the case side is formed into a gap smaller than other part; and
wherein the cover side positioning portion is composed of a first sandwiching piece and a second sandwiching piece which are arranged on an inner surface of the cover, are protruded to the case side, and are faced via the substrate,
the first sandwiching piece having an inclined portion inclined to the substrate side from a lower surface side plane portion of a protruding end portion of the first sandwiching piece toward the inner surface of the cover, and
the second sandwiching piece having an inclined portion inclined to the substrate side from an upper surface side plane portion of a protruding end portion of the second sandwiching piece toward the inner surface of the cover.

5. The electronic device according to claim 2,
wherein the case side positioning portion has an inclined portion by which a gap of the slide groove on the case side is formed into a gap smaller than other part; and
wherein the cover side positioning portion is composed of a first sandwiching piece and a second sandwiching piece which are arranged on an inner surface of the cover, are protruded to the case side, and are faced via the substrate,
the first sandwiching piece having an inclined portion inclined to the substrate side from a lower surface side plane portion of a protruding end portion of the first sandwiching piece toward the inner surface of the cover, and
the second sandwiching piece having an inclined portion inclined to the substrate side from an upper surface side plane portion of a protruding end portion of the second sandwiching piece toward the inner surface of the cover.

6. The electronic device according to claim 3,
wherein the case side positioning portion has an inclined portion by which a gap of the slide groove on the case side is formed into a gap smaller than other part; and
wherein the cover side positioning portion is composed of a first sandwiching piece and a second sandwiching piece which are arranged on an inner surface of the cover, are protruded to the case side, and are faced via the substrate,
the first sandwiching piece having an inclined portion inclined to the substrate side from a lower surface side plane portion of a protruding end portion of the first sandwiching piece toward the inner surface of the cover, and
the second sandwiching piece having an inclined portion inclined to the substrate side from an upper surface side plane portion of a protruding end portion of the second sandwiching piece toward the inner surface of the cover.

7. The electronic device according to claim 1,
wherein the case side positioning portion is provided in a protruding condition on both end sides of an innermost wall of the case and is composed of sandwiching bodies sandwiching the substrate by elastic force; and
wherein the cover side positioning portion is arranged on a central portion of an inner surface of the cover and is composed of sandwiching bodies sandwiching the substrate by elastic force.

8. The electronic device according to claim 2,
wherein the electronic component is arranged in a range of a line connecting the case side positioning portion on one side and the case side positioning portion on the other side, a line connecting the case side positioning portion on one side and the cover side positioning portion, and a line connecting the case side positioning portion on the other side and the cover side positioning portion.

9. The electronic device according to claim 1,
wherein the case has a convex portion provided in a protruding condition at least at a position of the electronic component.

10. The electronic device according to claim 9,
wherein the convex portion is provided with a through hole that passes through a surface of the case, and
a heat dissipation material is filled in the through hole and between the convex portion and the electronic component.

11. The electronic device according to claim 1,
wherein the case has a convex portion provided in a protruding condition at a position directly under the electronic component.

12. The electronic device according to claim 10,
wherein the convex portion provided on the case is that a height on an innermost wall side of the case is higher than a height on the cover side along an insertion direction of the substrate.

13. The electronic device according to claim 1,
wherein a fin is provided on the outside of the case.
An electronic device comprising:
a first substrate on which an electronic component is packaged;
a second substrate on which an electronic component is packaged;
a case in which a substrate insertion opening portion and an attaching opening portion are provided, a first slide groove through which the first substrate is inserted by sliding and a second slide groove through which the second substrate is inserted by sliding are formed on both sidewalls, the first substrate is contained by being inserted in the first slide groove from the substrate insertion opening portion, and the second substrate is contained by being inserted in the second slide groove from the substrate insertion opening portion; and
a cover which is coupled to the case to block the substrate insertion opening portion of the case,
wherein the case is provided with a case side first positioning portion which has a part of positioning a thickness direction of the first substrate and a part of positioning a direction perpendicular to a thickness of the first substrate and a case side second positioning portion which has a part of positioning a thickness direction of the second substrate and a part of positioning a direction perpendicular to a thickness of the second substrate;
the cover is provided with a cover side first positioning portion which has a part of positioning the thickness direction of the first substrate and a part of positioning the direction perpendicular to the thickness of the first substrate and a cover side second positioning portion which has a part of positioning the thickness direction of the second substrate and a part of positioning the direction perpendicular to the thickness of the second substrate; and
a relay member connecting the first substrate and the second substrate is provided between the first substrate and the second substrate.

14. An electronic device comprising:
a first substrate on which an electronic component is packaged;
a second substrate on which an electronic component is packaged;
a case in which a substrate insertion opening portion and an attaching opening portion are provided, a first slide groove through which the first substrate is inserted by sliding and a second slide groove through which the second substrate is inserted by sliding are formed on both sidewalls, the first substrate is contained by being inserted in the first slide groove from the substrate insertion opening portion, and the second substrate is contained by being inserted in the second slide groove from the substrate insertion opening portion; and
a cover which is coupled to the case to block the substrate insertion opening portion of the case,
wherein the case is provided with a case side first positioning portion which has a part of positioning a thickness direction of the first substrate and a part of positioning a direction perpendicular to a thickness of the first substrate and a case side second positioning portion which has a part of positioning a thickness direction of the second substrate and a part of positioning a direction perpendicular to a thickness of the second substrate;
the cover is provided with a cover side first positioning portion which has a part of positioning the thickness direction of the first substrate and a part of positioning the direction perpendicular to the thickness of the first substrate and a cover side second positioning portion which has a part of positioning the thickness direction of the second substrate and a part of positioning the direction perpendicular to the thickness of the second substrate; and
a relay member connecting the first substrate and the second substrate is provided between the first substrate and the second substrate.

15. The electronic device according to claim 14,
wherein the relay member is provided with a convex portion at a position facing the first substrate and a convex portion at a position facing the second substrate.

16. The electronic device according to claim 14,
wherein the first substrate is exposed to the outside of the case.

17. The electronic device according to claim 15,
wherein the first substrate is exposed to the outside of the case.

18. The electronic device according to claim 14,
wherein the case side first positioning portion is provided on both end sides of an innermost wall of the case, the case side first positioning portion including:
an inclined portion inclined from an upper surface of the first slide groove on the case side toward the first substrate and an inclined portion inclined from a lower surface of the first slide groove on the case side toward the first substrate,
a case side first plane portion going from an end portion on the first substrate side of the inclined portion on the upper surface side of the first slide groove toward an innermost portion on the case side,
a case side first projection body arranged between the first substrate and the case side first plane portion,
a case side second plane portion going from an end portion on the first substrate side of the inclined portion on the lower surface side of the first slide groove toward the innermost portion on the case side, and
a case side second projection body arranged between the first substrate and the case side second plane portion;
wherein the case side second positioning portion is provided on both end sides of the innermost wall of the case, the case side second positioning portion including:
an inclined portion inclined from an upper surface of the second slide groove on the case side toward the second substrate and an inclined portion inclined from a lower surface of the second slide groove on the case side toward the second substrate,
a case side third plane portion going from an end portion on the second substrate side of the inclined portion on the upper surface side of the second slide groove toward an innermost portion on the case side,
a case side third projection body which is arranged between the second substrate and the case side third plane portion and sandwiches the second substrate,
a case side fourth plane portion going from an end portion on the second substrate side of the inclined portion on the lower surface side of the second slide groove toward the innermost portion on the case side, and
a case side fourth projection body which is arranged between the second substrate and the case side fourth plane portion and sandwiches the second substrate;
wherein the cover side first positioning portion is arranged on a central portion of an inner surface of the cover and is composed of a first sandwiching piece and a second sandwiching piece which are protruded to the case side and face each other via the first substrate, the cover side first positioning portion including:
an inclined portion inclined to the first substrate side from a lower surface side plane portion of a protruding end portion of the first sandwiching piece toward an inner surface of the cover,
a cover side first plane portion going from an end portion on the first substrate side of the inclined portion toward the inner surface of the cover,
a cover side first projection body which is arranged between the first substrate and the cover side first plane portion and sandwiches the first substrate,
an inclined portion inclined to the first substrate side from an upper surface side plane portion of a protruding end portion of the second sandwiching piece toward the inner surface of the cover,
a cover side second plane portion going from an end portion on the first substrate side of the inclined portion toward the inner surface of the cover, and
a cover side second projection body which is arranged between the first substrate and the cover side second plane portion and sandwiches the first substrate; and
wherein the cover side second positioning portion is arranged on a central portion of an inner surface of the cover and is composed of a third sandwiching piece and a fourth sandwiching piece which are protruded to the case side and face each other via the second substrate, the cover side second positioning portion including:
an inclined portion inclined to the second substrate side from a lower surface side plane portion of a protruding end portion of the third sandwiching piece toward the inner surface of the cover,
a cover side third plane portion going from an end portion on the second substrate side of the inclined portion toward the inner surface of the cover,
a cover side third projection body which is arranged between the first substrate and the cover side third plane portion and sandwiches the second substrate,
an inclined portion inclined to the second substrate side from a lower surface side plane portion of a protruding end portion of the third sandwiching piece toward the inner surface of the cover,
a cover side fourth plane portion going from an end portion on the second substrate side of the inclined portion toward the inner surface of the cover, and
a cover side fourth projection body which is arranged between the first substrate and the cover side fourth plane portion and sandwiches the second substrate.

19. The electronic device according to claim 14,
wherein the electronic component packaged on the first substrate is arranged in a range of a line connecting the case side first positioning portion on one side and the case side first positioning portion on the other side, a line connecting the case side first positioning portion on one side and the cover side first positioning portion, and a line connecting the case side first positioning portion on the other side and the cover side first positioning portion; and
wherein the electronic component packaged on the second substrate is arranged in a range of a line connecting the case side second positioning portion on one side and the case side second positioning portion on the other side, a line connecting the case side second positioning portion on one side and the cover side second positioning portion, and a line connecting the case side second positioning portion on the other side and the cover side second positioning portion.

20. The electronic device according to claim 14,
wherein the relay member is provided with a first fastening portion which fastens and fixes the first substrate and a second fastening portion which fastens and fixes the second substrate.
